(19) United States
(12) Patent Application Publication
(10) Pub. No.: US 2025/0274031 A1
(43) Pub. Date: Aug. 28, 2025

(54) DRIVING CIRCUIT AND DRIVING METHOD FOR POWER SEMICONDUCTOR ELEMENT, AND POWER MODULE

(71) Applicant: Mitsubishi Electric Corporation, Tokyo (JP)

(72) Inventors: Kenichi MOROKUMA, Chiyoda-ku, Tokyo (JP); Takuya SAKAI, Chiyoda-ku, Tokyo (JP)

(73) Assignee: Mitsubishi Electric Corporation, Tokyo (JP)

(21) Appl. No.: 18/858,758

(22) PCT Filed: May 17, 2022
(86) PCT No.: PCT/JP2022/020535

§ 371 Date: Oct. 22, 2024

(51) Int. Cl. H02M 1/08; H03K 17/04; H03K 17/16

(52) U.S. Cl. CPC H02M 1/08; H03K 17/0406; H03K 17/168

(57) ABSTRACT

In a driving circuit for a power semiconductor element, a first gate voltage control circuit controls a gate voltage of the semiconductor element in response to a turn-on command, in a first time region, a second time region, and a third time region in order, in different manners for the respective time regions, to thereby cause a gate voltage to reach mirror voltage. The gate voltage reaches the mirror voltage in the second time region or the third time region according to magnitude of a main current flowing through the power semiconductor element. A second gate voltage control circuit controls the gate voltage greater than or equal to the mirror voltage.

### TECHNICAL FIELD

The present disclosure relates to a driving circuit and a driving method for a power semiconductor element and to a power module.

### BACKGROUND ART

A power semiconductor element that controls large amounts of electric power is used for, for example, a power supply circuit that generates alternating currents (ACs) with different frequencies from direct current (DC) and AC, and a power converter including a power supply circuit. When the power semiconductor element is used for a power converter such as an inverter, it is important to reduce power consumption from the viewpoints of energy conservation and greenhouse gas reduction.

Japanese National Patent Publication No. 2008-519529 (PTL 1) discloses a method of reducing energy consumed in a power semiconductor element by controlling switching of the power semiconductor element.

Specifically, this literature discloses a “method of driving a power transistor switch comprising: receiving a drive input signal; converting the drive input signal into a converted drive input signal; and applying the converted gate drive input signal to a control electrode of the switch to turn on the switch, the converted drive input signal having three regions with respect to time, each having a slope, a first region in time having a first slope up to a Miller Plateau of the switch; a second region in time having a second slope with a reduced sloped compared with the first slope; and a third region having a third slope that is greater than the second slope, whereby the control electrode voltage rapidly reaches the Miller Plateau voltage, then more slowly reaches a threshold voltage of the switch and then, when the switch has substantially fully turned on, the control electrode voltage is rapidly increased. The switch delay time is also maintained substantially constant by adjusting the transistor control electrode precharge voltage” (see ABSTRACT of Japanese National Patent Publication No. 2008-519529).

### CITATION LIST

### Patent Literature

PTL 1: Japanese National Patent Publication No. 2008-519529

### SUMMARY OF INVENTION

### Technical Problem

The method of controlling a power semiconductor element disclosed in Japanese National Patent Publication No. 2008-519529 (PTL 1) can reduce a current change rate (dl/dt) during switching to reduce electromagnetic interference (EMI). However, control to reduce the current change rate when a large current I flows through the power semiconductor element may increase a switching time, which in turn increases a switching loss. The above literature does not take this problem into account.

The present disclosure has been made in view of the above problem. An object of the present disclosure is to provide a driving circuit for a power semiconductor element which is capable of reducing a switching loss even when a relatively large current flows through the power semiconductor element.

### Solution to Problem

A driving circuit for a power semiconductor element according to an embodiment includes a first gate voltage control circuit and a second gate voltage control circuit. The first gate voltage control circuit controls a gate voltage of the power semiconductor element in response to a turn-on command of the power semiconductor element, in a first time region, a second time region, and a third time region in order, in different manners for the respective time regions, to thereby cause the gate voltage to reach a mirror voltage The gate voltage reaches the mirror voltage in the second time region or the third time region according to magnitude of a main current flowing through the power semiconductor element. The second gate voltage control circuit controls the gate voltage greater than or equal to the mirror voltage.

### Advantageous Effects of Invention

According to the embodiment described above, the driving circuit controls a gate voltage of the power semiconductor element in response to a turn-on command of the power semiconductor element, in a first time region, a second time region, and a third time region in order, in different manners for the respective time regions, to thereby cause the gate voltage to reach a mirror voltage. Thus, a switching loss can be reduced even when a relatively large current flows through the power semiconductor element.

### BRIEF DESCRIPTION OF DRAWINGS

FIG. 1 is a block diagram showing a configuration of a driving circuit for a power semiconductor element according to Embodiment 1.

FIG. 2 shows an example configuration of a voltage limiting circuit.

FIG. 3 shows an example configuration of a first change voltage generation circuit.

FIG. 4 shows an example configuration of the first change voltage generation circuit.

FIG. 5 shows an example configuration of a second change voltage generation circuit.

FIG. 6 shows an example configuration of the second change voltage generation circuit.

FIG. 7 shows an example configuration of a comparator circuit.

FIG. 8 shows an example configuration of an adder circuit.

FIG. 9 shows an example configuration of a buffer circuit.

FIG. 10 shows an example configuration of the buffer circuit.

FIG. 11 shows an example configuration of the buffer circuit.

FIG. 12 shows an example configuration of a power semiconductor element.

FIG. 13 is a timing chart for describing a first operation example of a driving circuit for a power semiconductor element according to Embodiment 1.

FIG. 14 is a timing chart for describing a second operation example of the driving circuit for a power semiconductor element according to Embodiment 1.

FIG. 15 is a flowchart showing a control procedure during turn-on of the power semiconductor element by the driving circuit of Embodiment 1.

FIG. 16 shows an example implementation of the driving circuit of Embodiment 1.

FIG. 17 shows a modification of the implementation of FIG. 16.

FIG. 18 shows another example implementation of the driving circuit of Embodiment 1.

FIG. 19 shows a modification of the implementation of FIG. 18.

FIG. 20 shows a configuration of a driving circuit for a power semiconductor element according to Embodiment 2.

FIG. 21 shows an example configuration of a mirror voltage detection circuit.

FIG. 22 shows an example configuration of a differentiating circuit.

FIG. 23 shows an example configuration of the differentiating circuit.

FIG. 24 shows an example configuration of a binarization circuit.

FIG. 25 shows an example configuration of an edge detection circuit.

FIG. 26 shows an example configuration of a flip-flop circuit.

FIG. 27 shows an example configuration of an inverter circuit.

FIG. 28 is a timing chart for describing an operation example of the driving circuit for a power semiconductor according to Embodiment 2.

FIG. 29 is a flowchart showing a control procedure during turn-on of the power semiconductor element by the driving circuit of Embodiment 2.

### DESCRIPTION OF EMBODIMENTS

The embodiments will be described below in detail with reference to the drawings. The same or corresponding components have the same reference characters allotted, and description thereof will not be repeated.

### Embodiment 1

### [Configuration of Driving Circuit for Power Semiconductor Element]

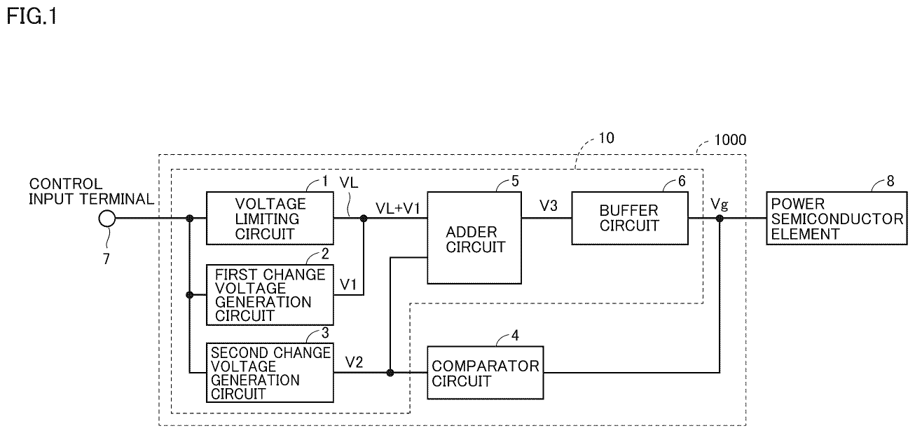

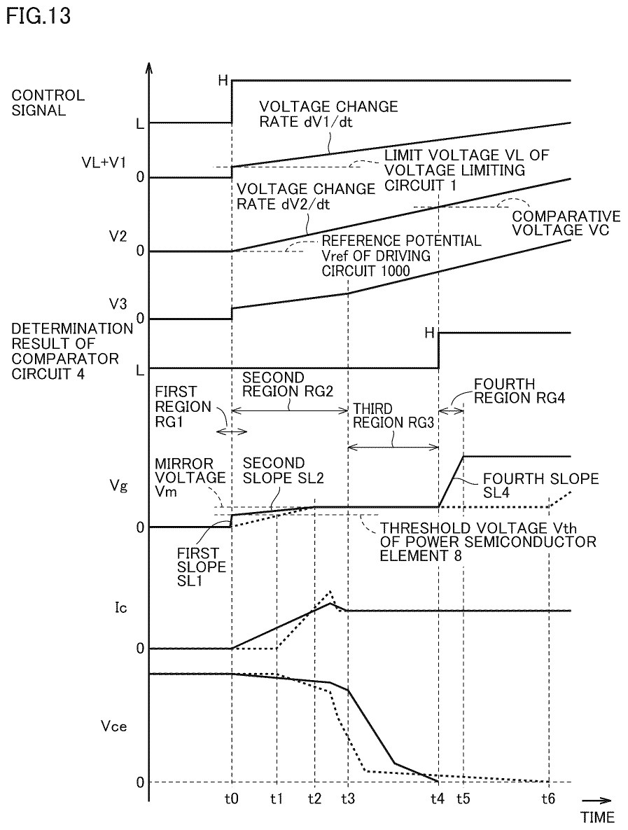

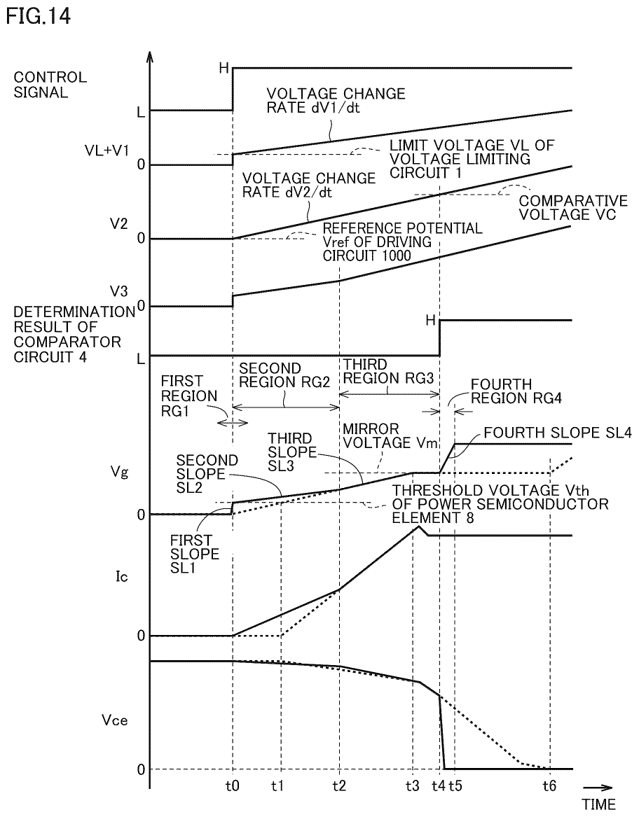

FIG. 1 is a block diagram showing a configuration of a driving circuit 1000 for a power semiconductor element according to Embodiment 1, Driving circuit 1000 generates a gate voltage Vg for controlling switching of a power semiconductor element 8 according to a control signal input to a control input terminal 7. More specifically, driving circuit 1000 controls voltage changes of gate voltage Vg during turn-on operation of power semiconductor element 8 in four time regions of a first time region (RG1 of FIGS. 13 and 14) to a fourth time region (RG4 of FIGS. 13 and 14) in order. The first to fourth time regions will also be simply referred to as first to fourth regions below.

As shown in FIG. 1, driving circuit 1000 includes a voltage limiting circuit 1, a first change voltage generation circuit 2, a second change voltage generation circuit 3, a comparator circuit 4, an adder circuit 5, and a buffer circuit 6. Herein, voltage limiting circuit 1, first change voltage generation circuit 2, second change voltage generation circuit 3, adder circuit 5, and buffer circuit 6 are collectively referred to as a first gate voltage control circuit 10. First gate voltage control circuit 10 controls gate voltage Vg of power semiconductor element 8 in response to a turn-on command, in first time region RG1, second time region RG2, and third time region RG2 in order, in different manners for the respective time regions, to thereby cause gate voltage Vg to reach a mirror voltage Vm. Comparator circuit 4 serving as a second gate voltage control circuit controls gate voltage Vg after a mirror period. The function of each circuit will be briefly described below.

Voltage limiting circuit 1 controls voltage changes of gate voltage Vg in first region RG1. Specifically, voltage limiting circuit 1 outputs a limit voltage VL (also referred to as a first voltage) in response to the turn-on command, thereby suddenly increasing gate voltage Vg to limit voltage VL at a first slope (SL1 of FIGS. 13 and 14). In other words, voltage limiting circuit 1 limits gate voltage Vg to limit voltage VL at start-up of power semiconductor element 8. Preferably, limit voltage VL corresponds to a threshold voltage Vth of power semiconductor element 8 and has a value approximately equal to threshold voltage Vth.

First change voltage generation circuit 2 controls voltage changes of gate voltage Vg in second region RG2. Specifically, first change voltage generation circuit 2 generates a first change voltage V1 that increases at a second slope (SL2 of FIGS. 13 and 14) gentler than first slope SL1. First change voltage generation circuit 2 supplies the generated first change voltage V1 to a gate of power semiconductor element 8 via buffer circuit 6, thereby increasing gate voltage Vg from limit voltage VL at second slope SL2.

Second change voltage generation circuit 3 controls voltage changes of gate voltage Vg in third region RG3. Specifically, second change voltage generation circuit 3 generates a second change voltage V2 that abruptly changes than first change voltage V1 output from first change voltage generation circuit 2. Thus, when gate voltage Vg has not reached the mirror voltage at the time at which a first period (from times t0 to t3 of FIG. 13, from times t0 to t2 of FIG. 14) has elapsed since the receipt of the turn-on command, gate voltage Vg increases to the mirror voltage at a third slope SL3 gentler than first slope SL1 described above and steeper than second slope SL2.

Comparator circuit 4 controls voltage changes of gate voltage Vg in fourth region RG4. Specifically, comparator circuit 4 increases gate voltage Vg from the mirror voltage at a fourth slope SL4 steeper than third slope SL3 described above from the time at which a second period (from times t0 to t4 of FIGS. 13 and 14) has elapsed since the receipt of the turn-on command. Finally, gate voltage Vg reaches a supply voltage supplied to driving circuit 1000.

Adder circuit 5 outputs a voltage obtained by addition of first change voltage V1 to limit voltage VL until the first period described above has elapsed since the receipt of the turn-on command. From the time at which the first period described above has elapsed since the receipt of the turn-on command, adder circuit 5 outputs a current obtained by addition of an output current of voltage limiting circuit 1, an output current of first change voltage generation circuit 2, and an output current of second change voltage generation circuit 3, and outputs a third change voltage V3 based on limit voltage VL, first change voltage V1, and second change voltage V2 described above. Buffer circuit 6 transfers an output voltage of adder circuit 5 to the gate of power semiconductor element 8, thereby generating gate voltage Vg of power semiconductor element 8.

To summarize the four time regions described above, first region RG1 corresponds to a rise of gate voltage Vg immediately after the receipt of the turn-on command. Second region RG2 is a time region until the first period described above has elapsed since the rise of gate voltage Vg. Third region RG3 is a time region until the second period has elapsed since the lapse of the first period described above. Fourth region RG4 is a time region until gate voltage Vg reaches the supply voltage of driving circuit 1000 from the lapse of the second period described above.

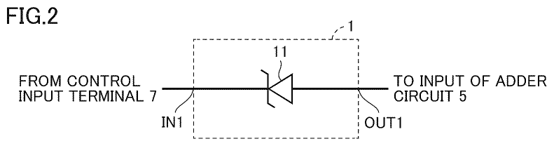

FIG. 2 shows an example configuration of voltage limiting circuit 1. In one example, voltage limiting circuit 1 is formed of a Zener diode 11.

As shown in FIG. 2, voltage limiting circuit 1 has an input node IN1 connected to control input terminal 7 for controlling power semiconductor element 8 from outside. Voltage limiting circuit 1 has an output node OUT1 connected to adder circuit 5. In voltage limiting circuit 1, Zener diode 11 has a cathode connected to input node IN1 and an anode connected to output node OUT1.

With the configuration of voltage limiting circuit 1 described above, voltage limiting circuit 1 limits voltage changes at output node OUT1 when the control signal input to control input terminal 7 as a turn-on operation command changes from low to high. Specifically, the voltage at output node OUT1 of voltage limiting circuit 1 remains unchanged until the voltage at input node IN1 of voltage limiting circuit 1 reaches a Zener voltage (also referred to as limit voltage VL below) of Zener diode 11, and is then limited to the Zener voltage. Consequently, voltage limiting circuit 1 generates a voltage that abruptly changes, and controls voltage changes of gate voltage Vg in first region RG1.

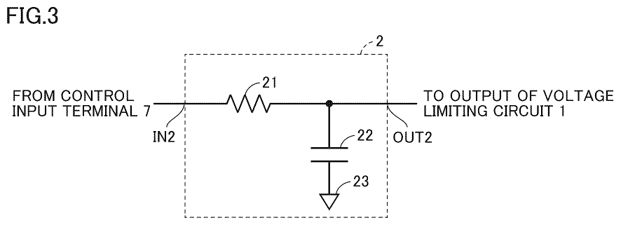

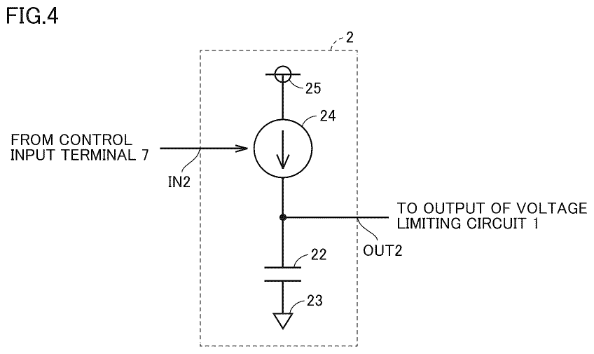

Each of FIGS. 3 and 4 shows an example configuration of first change voltage generation circuit 2. First change voltage generation circuit 2 has an input node IN2 connected to control input terminal 7 and an output node OUT2 connected to output node OUT1 of voltage limiting circuit 1. When the control signal input to control input terminal 7 as the turn-on operation command changes from low to high, first change voltage generation circuit 2 generates first change voltage V1, which increases relatively gently at a first temporal change rate dV1/dt, with reference to limit voltage VL that is a voltage value limited by voltage limiting circuit 1, and outputs first change voltage V1 to adder circuit 5. Consequently, first change voltage generation circuit 2 controls temporal changes (corresponding to first slope SL1) of gate voltage Vg in second region RG2 before gate voltage Vg reaches the mirror voltage.

Specifically, in the example configuration of FIG. 3, first change voltage generation circuit 2 is configured as a first-order lag circuit including a resistive element 21 and a capacitive element 22. Resistive element 21 is connected between input node IN2 and output node OUT2. Capacitive element 22 is connected between output node OUT2 and a reference node 23 to which a reference potential Vref is applied. With this configuration, the voltage at output node OUT2 increases relatively gently from limit voltage VL at an almost constant temporal increase rate according to a time constant CR determined by a resistance value R of resistive element 21 and a capacitance value C of capacitive element 22.

In the example configuration of FIG. 4, first change voltage generation circuit 2 includes a constant current source 24 and capacitive element 22. Constant current source 24 is connected between a power supply node 25, to which a supply voltage is applied, and output node OUT2. Capacitive element 22 is connected between output node OUT2 and reference node 23. Constant current source 24 starts flowing a constant current to capacitive element 22 when the control signal, input to control input terminal 7 as the turn-on operation command, changes from low to high. Thus, the voltage of capacitive element 22 increases at a constant temporal change rate from limit voltage VL.

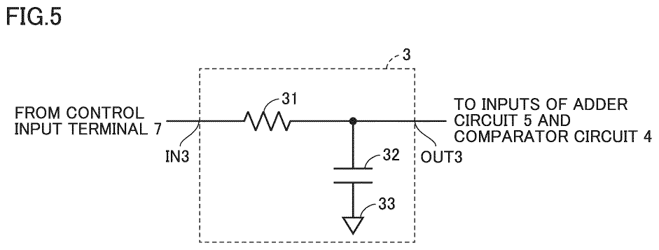

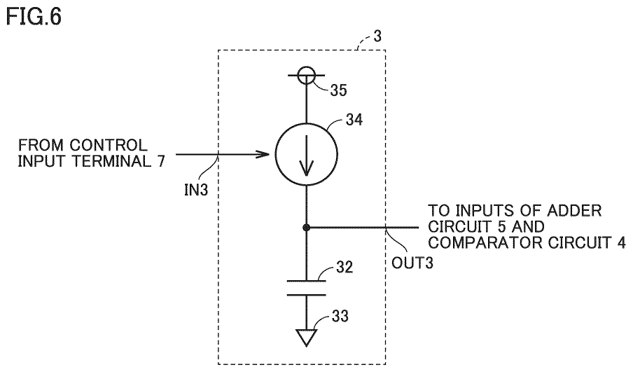

Each of FIGS. 5 and 6 shows an example configuration of second change voltage generation circuit 3. Second change voltage generation circuit 3 has an input node IN3 connected to control input terminal 7 and an output node OUT3 connected to comparator circuit 4 and adder circuit 5. When the control signal, input to control input terminal 7 as the turn-on operation command, changes from low to high, second change voltage generation circuit 3 generates second change voltage V2, which increases relatively gently at a second temporal change rate dV2/dt, with reference to reference potential Vref of driving circuit 1000 and outputs second change voltage V2. Herein, second change rate dV2/dt is greater than first change rate dV1/dt described above. A time change (corresponding to third slope SL3) of gate voltage Vg in third region RG3 before gate voltage Vg reaches the mirror voltage is based on temporal change rate dV2/dt of second change voltage V2 output from second change voltage generation circuit 3.

Specifically, in the example configuration of FIG. 5, second change voltage generation circuit 3 is configured as a first-order lag circuit including a resistive element 31 and a capacitive element 32, as in the case of FIG. 3. Resistive element 31 is connected between input node IN3 and output node OUT3. Capacitive element 33 is connected between output node OUT3 and a reference node 33 to which reference potential Vref is applied. With this configuration, the voltage at output node OUT3 increases relatively gently at an almost constant increase rate from reference potential Vref according to time constant CR determined by resistance value R of resistive element 31 and capacitance value C of capacitive element 33.

In the example configuration of FIG. 6, second change voltage generation circuit 3 includes a constant current source 34 and capacitive element 32, as in the case of FIG. 4. Constant current source 34 is connected between a power supply node 35, to which the supply voltage is applied, and output node OUT3. Capacitive element 33 is connected between output node OUT3 and reference node 33. Constant current source 34 starts flowing a constant current to capacitive element 33 when the control signal, input into control input terminal 7 as the turn-on operation command, changes from low to high. Consequently, the voltage of capacitive element 33 increases at a constant temporal increase rate from reference potential Vref.

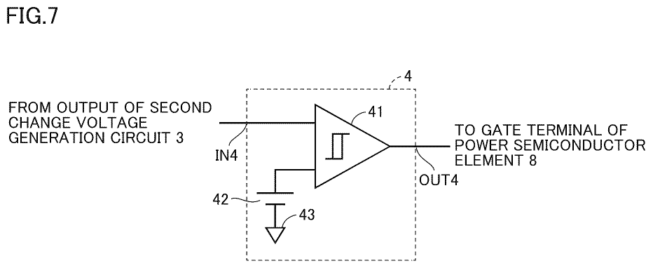

FIG. 7 shows an example configuration of comparator circuit 4. As shown in FIG. 7, comparator circuit 4 includes a comparator 41 and a comparative voltage source 42, Comparator circuit 4 has an input node IN4 connected to output node OUT3 of second change voltage generation circuit 3 and an output node OUT4 connected to the gate terminal of power semiconductor element 8. In comparator circuit 4, comparator 41 has a non-inverting input terminal connected to input node IN4, an inverting input terminal connected to comparative voltage source 42, and an output terminal connected to output node OUT4.

With the configuration of comparator circuit 4 described above, comparator circuit 4 outputs a low level (i.e., reference potential Vref of driving circuit 1000) until second change voltage V2 output from second change voltage generation circuit 3 reaches a voltage value (i.e., comparative voltage VC) of comparative voltage source 42, and then, outputs a high level (i.e., a supply voltage of driving circuit 1000). Consequently, comparator circuit 4 generates a voltage that abruptly increases at fourth slope SL4 and controls changes in gate voltage Vg in the fourth region where gate voltage Vg becomes greater than or equal to the mirror voltage. Comparator circuit 4 may be configured to compare first change voltage V1 output from first change voltage generation circuit 2 with comparative voltage VC. The value of comparative voltage VC is adjusted according to voltage change rage dV1/dt of first change voltage V1.

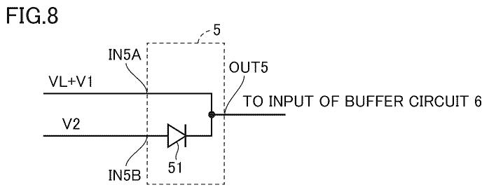

FIG. 8 shows an example configuration of adder circuit 5. As shown in FIG. 8, adder circuit 5 includes a diode 51. Adder circuit 5 has an input node IN5A connected to output node OUT1 of voltage limiting circuit 1 and output node OUT2 of first change voltage generation circuit 2. Adder circuit 5 has an input node IN5B connected to output node OUT3 of second change voltage generation circuit 3. Adder circuit 5 has an output node OUT5B connected to an input node IN6 of buffer circuit 6. In adder circuit 5, input node IN5A is directly connected to output node OUT5 through wiring, Diode 51 is connected between input node IN5B and output node OUT5 such that the direction from input node IN5B to output node OUT5 is the forward direction.

With the configuration of adder circuit 5 described above, until second change voltage V2, which is output from second change voltage generation circuit 3 and increases at the second change rate, reaches a resultant voltage (VL+V1) of limit voltage VL output from voltage limiting circuit 1 and first change voltage V1, which is output from first change voltage generation circuit 2 and increases at the first change rate, adder circuit 5 outputs the resultant voltage (VL+V1) from output node OUT5. Subsequently, adder circuit 5 outputs a current obtained by addition of the output current of voltage limiting circuit 1, the output current of first change voltage generation circuit 2, and the output current of second change voltage generation circuit 3, and outputs a third change voltage V3 based on the resultant voltage (VL+V1) and second change voltage V2. The value of third change voltage V3 depends on the characteristics, parasitic capacitance, or the like of diode 51. A temporal change rate dV3/dt of third change voltage V3 becomes greater than temporal change rate dV1/dt of first change voltage V1. The first period described above corresponds to a period until second change voltage V2 becomes equal to the sum of limit voltage VL and first change voltage V1.

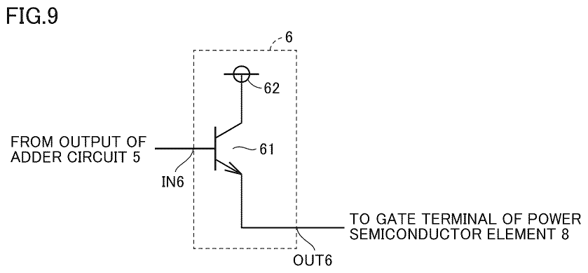

Each of FIGS. 9, 10, and 11 shows an example configuration of buffer circuit 6. Buffer circuit 6 transfers the output voltage of adder circuit 5, input via input node IN6, to the gate of power semiconductor element 8 via output node OUT6, thereby generating gate voltage Vg of power semiconductor element 8.

Specifically, in the example configuration of FIG. 9, buffer circuit 6 is formed of an emitter follower of an NPN-type bipolar transistor 61. The voltage amplification factor of the emitter follower is one. More specifically, bipolar transistor 61 has a collector connected to a power supply node 62 to which the supply voltage is applied, an emitter connected to output node OUT6, and a base connected to input node IN6.

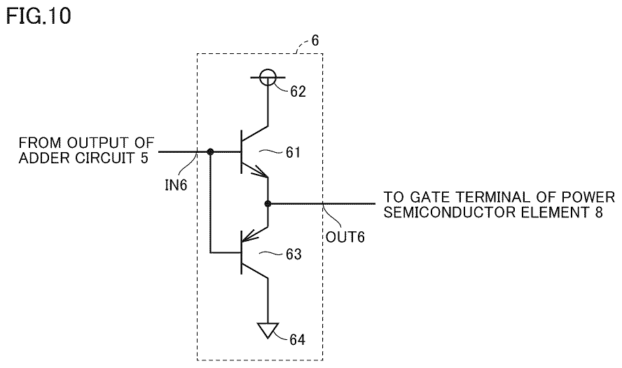

In the example configuration of FIG. 10, buffer circuit 6 is formed of a push-pull emitter follower of NPN-type bipolar transistor 61 and a PNP-type bipolar transistor 63. The voltage amplification factor of the emitter follower is one. More specifically, the collector of bipolar transistor 61 is connected to power supply node 62 to which a power supply potential is applied, and a collector of bipolar transistor 63 is connected to a reference node 64 to which reference potential Vref is applied. Emitters of bipolar transistors 61, 63 are connected to output node OUT6. Bases of bipolar transistors 61 and 63 are connected to input node IN6.

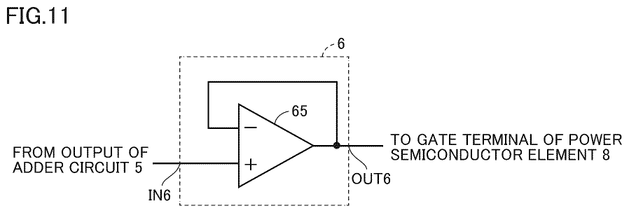

In the example configuration of FIG. 11, buffer circuit 6 is formed of a unity gain buffer using an operational amplifier 65. More specifically, operational amplifier 65 has an output terminal connected to output node OUT6 and connected to an inverting input terminal of operational amplifier 65. Operational amplifier 65 has a non-inverting input terminal connected to input node IN6.

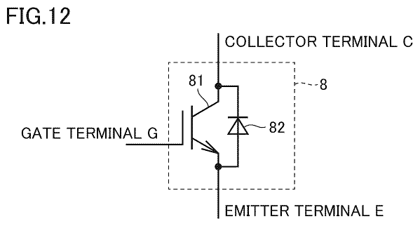

FIG. 12 shows an example configuration of power semiconductor element 8. In the example shown in FIG. 12, power semiconductor element 8 is formed of an insulated gate bipolar transistor (IGBT) 81 and a freewheel diode 82. The IGBT may be a field effect transistor (FET) or a bipolar transistor, and the type of the semiconductor element is not particularly limited. In the present disclosure, a control electrode of power semiconductor element 8 is also referred to as a gate, and the voltage of the control electrode is also referred to as a gate voltage.

### [Operation of Driving Circuit for Power Semiconductor Element]

Next, description will be given of an operation of driving circuit 1000 of Embodiment 1 during turn-on of power semiconductor element 8. The following will describe an operation when a collector current Ic, which is a main current of power semiconductor element 8, is relatively small with reference to FIG. 13, and describe an operation when collector current Ic of power semiconductor element 8 is relatively large with reference to FIG. 14. Driving circuit 1000 for a power semiconductor element according to Embodiment 1 is characterized in that gate voltage Vg of power semiconductor element 8 is controlled by a different method depending on whether collector current Ic is small or large.

FIG. 13 is a timing chart for describing a first operation example of driving circuit 1000 for a power semiconductor element according to Embodiment 1. FIG. 13 shows a timing chart when collector current Ic is relatively small during turn-on operation of power semiconductor element 8. Waveforms of a control signal input to control input terminal 7, the sum (VL+V1) of limit voltage VL output from voltage limiting circuit 1 and first change voltage V1 output from first change voltage generation circuit 2, second change voltage V2 output from second change voltage generation circuit 3, output voltage V3 of adder circuit 5, a determination result of comparator circuit 4, and gate voltage Vg, collector current Ic, and a collector-emitter voltage Vce of power semiconductor element 8 are shown in order from the top of FIG. 13. For the waveforms of gate voltage Vg, collector current Ic, and collector-emitter voltage Vce, the case of the present embodiment is indicated by the solid line, and the case of a comparative example is indicated by the dashed line. The comparative example shows a case of a driving circuit of a constant voltage driving type, in which gate voltage Vg of power semiconductor element 8 is not controlled separately in a plurality of time regions, or a constant current driving type.

Description will be given below in chronological order. First, an operation of driving circuit 1000 at time to of FIG. 13 will be described.

At time t0, when the control signal input to control input terminal 7 as the turn-on operation command changes from low to high, voltage limiting circuit 1, first change voltage generation circuit 2, and second change voltage generation circuit 3 start operating. Voltage changes of gate voltage Vg in first region RG1 in the vicinity of time t0 are controlled by voltage limiting circuit 1.

Specifically, output voltage V1 of voltage limiting circuit 1 suddenly rises at first slope SL1 to limit voltage VL. Herein, limit voltage VL of voltage limiting circuit 1 is set to approximately threshold voltage Vth of power semiconductor element 8. Consequently, as gate voltage Vg reaches threshold voltage Vth of power semiconductor element 8, collector current Ic starts flowing through power semiconductor element 8. Contrastingly, in the case of the driving circuit of the comparative example, gate voltage Vg starts rising but it takes time for gate voltage Vg to reach threshold voltage Vth, and accordingly, collector current Ic does not rise immediately. Thus, compared with the driving circuit of the comparative example, driving circuit 1000 according to Embodiment 1 can cause gate voltage Vg in first region ROI to abruptly rise to approximately the threshold voltage at first slope SL1, thereby reducing a dead time for a smaller loss.

At time t0, further, output voltage V1 of first change voltage generation circuit 2 starts rising at first temporal change rate dV1/dt with reference to limit voltage VL of voltage limiting circuit 1. Also, output voltage V2 of second change voltage generation circuit 3 starts rising at second temporal change rate dV2/dt with reference to reference potential Vref of driving circuit 1000. Herein, in driving circuit 1000 of Embodiment 1, change rate dV2/dt of second change voltage V2 generated in second change voltage generation circuit 3 is greater than change rate dV1/dt of first change voltage V1 generated in first change voltage generation circuit 2.

In the vicinity of time t0, since the sum of limit voltage VL and first change voltage V1 output respectively from voltage limiting circuit 1 and first change voltage generation circuit 2 is greater than second change voltage V2 output from second change voltage generation circuit 3, output voltage V3 of adder circuit 5 becomes equal to the sum of limit voltage VL and first change voltage V1. A determination result of comparator circuit 4 is the low (L) level because output voltage V2 of second change voltage generation circuit 3 is smaller than the output voltage (i.e., comparative voltage VC) of comparative voltage source 42.

Changes in gate voltage Vg, collector current Ic, and collector-emitter voltage Vce of power semiconductor element 8 in the vicinity of time t0 will be described below while making a comparison between the comparative example and the present embodiment. As the control signal that is the turn-on operation command changes from low to high, the operation of voltage limiting circuit 1 causes gate voltage Vg in the present embodiment to abruptly increase at first slope SL1 in first region RG1 to reach threshold voltage Vth. Contrastingly, in the case of the driving circuit of the comparative example, as the control signal that is the turn-on operation command changes from low to high, gate voltage Vg gently starts rising but does not immediately reach threshold voltage Vth.

Collector current Ic in the present embodiment starts flowing immediately because gate voltage Vg reaches threshold voltage Vth based on limit voltage VL set in voltage limiting circuit 1. Collector current Ic in the comparative example remains unchanged at zero because gate voltage Vg has not reached threshold voltage Vth.

Collector-emitter voltage Vce of power semiconductor element 8 starts decreasing under the influence of change rate dIc/dt of collector current Ic, which starts flowing. Collector-emitter voltage Vce in the comparative example remains unchanged because collector current Ic does not flow.

Next, an operation of driving circuit 1000 from times t0 to t1 of FIG. 13 will be described. Voltage limiting circuit 1 outputs limit voltage VL, and first change voltage generation circuit 2 outputs first change voltage V1 that increases at first change rate dV1/dt. Thus, the resultant voltage (VL+V1) obtained by addition of these voltages rises at first change rate dV1/dt with reference to limit voltage VL. Output voltage V2 of second change voltage generation circuit 3 rises at second change rate dV2/dt with reference to reference potential Vref of driving circuit 1000.

Since the resultant voltage (VL+V1) is greater than second change voltage V2 described above, output voltage V3 of adder circuit 5 increases at first change rate dV1/dt with reference to limit voltage VL. The determination result of comparator circuit 4 remains low because output voltage V2 of second change voltage generation circuit 3 is smaller than comparative voltage VC.

Gate voltage Vg in the present embodiment suddenly rises at first slope SL1 to threshold voltage Vth in first region RG1 in the vicinity of time t0. Subsequently, in second region RG2, gate voltage Vg rises at a relatively gentle change rate at second slope SL2 based on change rate dV1/dt of the output voltage of first change voltage generation circuit 2. Gate voltage Vg in the case of the driving circuit of the comparative example reaches threshold voltage Vth of power semiconductor element 8 at time t1.

In the present embodiment, collector current Ie of power semiconductor element 8 rises at the current change rate based on gate voltage Vg that changes at second slope SL2 in second region RG2. Collector current Ic in the case of the driving circuit of the comparative example starts flowing because gate voltage Vg reaches threshold voltage Vth at time t1.

Collector-emitter voltage Vce in the present embodiment decreases under the influence of the change rate of collector current Ic. Collector-emitter voltage Vce in the case of the driving circuit of the comparative example remains unchanged while collector current Ic is not flowing and starts decreasing after collector current Ic starts flowing at time t1.

Next, an operation of driving circuit 1000 from times t1 to t2 of FIG. 13 will be described. Output voltage V1 of voltage limiting circuit 1 and first change voltage generation circuit 2, output voltage V2 of second change voltage generation circuit 3, output voltage V3 of adder circuit 5, and the output of comparator circuit 4 are similar to those in the case of times t0 to t1, and accordingly, description thereof will not be repeated.

In second region RG2, gate voltage Vg in the present embodiment rises relatively gently at the second slope based on voltage change rate dV1/dt of the output voltage of first change voltage generation circuit 2 as in the case of time t0 to time t1, and reaches the mirror voltage at time t2. Gate voltage Vg in the case of the driving circuit of the comparative example reaches the threshold voltage at time t1. In the case of the driving circuit of the comparative example, thus, collector current Ic starts flowing from time t1.

Herein, the change rate of gate voltage Vg in the comparative example is greater than the change rate of gate voltage Vg corresponding to second slope SL2 in second region RG2 in the present embodiment. Thus, change rate dIc/dt of collector current Ic in the comparative example is greater than change rate dIc/dt of collector current Ic in the present embodiment. As a result, a switching loss of power semiconductor element 8 in second region RG2 in the present embodiment is larger than in the case of the driving circuit of the comparative example. In the case of FIG. 13, however, the influence of this loss is small because collector current Ic is relatively small.

Changes in collector-emitter voltage Vce of power semiconductor element 8 are affected by change rate dIc/dt of collector current Ic. Consequently, change rate dIc/dt is greater in the case of the driving circuit of the comparative example than in the present embodiment, and also, the change rate of collector-emitter voltage Vce is greater in the case of the driving circuit of the comparative example than in the present embodiment.

Next, an operation of driving circuit 1000 from times t2 to t3 of FIG. 13 will be described. Since output voltage V1 of voltage limiting circuit 1 and first change voltage generation circuit 2 and output voltage V2 of second change voltage generation circuit 3 are similar to those in the case of times t0 to t2, description thereof will not be repeated.

As in the case of time t to time t2, until time t3 is reached, the sum (VL+V1) of limit voltage VL output from the voltage limiting circuit and first change voltage V1 output from first change voltage generation circuit 2 is greater than second change voltage V2 output from second change voltage generation circuit 3. Thus, output voltage V3 of adder circuit 5 is equal to the sum of limit voltage VL and first change voltage V1. At and after time t3, second change voltage V2 is greater than the sum (VL+V1) of limit voltage V and first change voltage V1, and accordingly, output voltage V3 of adder circuit 5 has the value based on limit voltage VL, first change voltage V1, and second change voltage V2, and the change rate thereof is greater than dV1/dt. Also, the output current of adder circuit 5 is equal to the sum of the output current of voltage limiting circuit 1, the output current of first change voltage generation circuit 2, and the output current of second change voltage generation circuit 3. Herein, second region RG2 is a period (the first period described above) from gate voltage Vg suddenly changing at first slope SL1 in first region RG1 to time t3.

In the case of FIG. 13, gate voltage Vg reaches the mirror period in second region RG2 where collector current Ic of power semiconductor element 8 is small. Second region RG2 includes a period of time (until time t3 in FIG. 13) in which a recovery current starts flowing and then recovers. In second region RG2, driving circuit 1000 is characterized by controlling gate voltage Vg based on first change voltage V1 having relatively gentle voltage change rate dV1/dt which is generated in first change voltage generation circuit 2.

Gate voltage Vg in second region RG2 in the present embodiment changes at second slope SL2 based on voltage change rate dV1/dt set in first change voltage generation circuit 2, and accordingly, a change rate of gate voltage Vg is smaller and change rate dIc/dt of collector current Ic during recovery is also smaller than in the case of the driving circuit of the comparative example. As a result, change rate dVce/dt of collector-emitter voltage Vce by the recovery current can be smaller, thus reducing EMI.

The above description is based on the premise that change rate dIc/dt of collector current Ic in second region RG2 in the present embodiment is smaller than in the case of the driving circuit of the comparative example. However, change rate dIc/dt of collector current Ic in the present embodiment is greater than in the case of the driving circuit of the comparative example, depending on how to set change rate dV1/dt of first change voltage V1 output from first change voltage generation circuit 2. In that case, EMI due to the recovery current is larger in the present embodiment than in the comparative example, but the present embodiment is advantageous in that a switching loss in second region RG2 can be reduced more.

Next, an operation of driving circuit 1000 from times t3 to t4 of FIG. 13 will be described. At and after time t3, second change voltage V2 output from second change voltage generation circuit 3 is greater than the sum of limit voltage VL output from voltage limiting circuit 1 and first change voltage V1 output from first change voltage generation circuit 2. Thus, output voltage V3 of adder circuit 5 changes based on limit voltage VL and first change voltage V1, as well as second change voltage V2, at and after time t3.

Third region RG3 is a period in which gate voltage Vg is controlled mainly based on output voltage V2 of second change voltage generation circuit 3. However, since gate voltage Vg has reached the mirror period at time t2 in second region RG2, gate voltage Vg is constant in third region RG3. Similarly, gate voltage Vg has reached the mirror voltage at time t2 in the case of the driving circuit of the comparative example, gate voltage Vg is constant in third region RG3.

Collector current Ic of power semiconductor element 8 is constant at and after time t3 because the recovery current has been recovered at time t3. Collector current Ic is also constant at and after time 3 also in the case of the driving circuit of the comparative example. Collector-emitter Vce of power semiconductor element 8 decreases at voltage change rate dVce/dt corresponding to the driving capability of buffer circuit 6. Also in the case of the driving circuit of the comparative example, collector-emitter voltage Vce decreases at the voltage change rate corresponding to the driving capability of the driving circuit.

Next, an operation of driving circuit 1000 from time t4 to a time t5 of FIG. 13 will be described. At time t4, output voltage V2 of second change voltage generation circuit 3 which is input to comparator circuit 4 reaches comparative voltage VC of comparator circuit 4. As a result, the determination result of comparator circuit 4 changes from low to high. When the determination result of comparator circuit 4 changes to high, a current is injected into the gate terminal of power semiconductor element 8, and accordingly, gate voltage Vg suddenly rises at fourth slope SL4. A period from time t0 to time t4 corresponds to the second period described above.

Fourth region RG4 is a time region in which gate voltage Vg increases at fourth slope SL4 based on changes in the output voltage of comparator circuit 4. In other words, fourth region RG4 is a period from an end of the mirror period of gate voltage Vg (time t4) to a time at which gate voltage Vg reaches the supply voltage of driving circuit 1000 (time t5). Contrastingly, also at and after time t5, gate voltage Vg in the driving circuit of the comparative example has been in the mirror period until a time to, causing a loss due to switching during the mirror period.

As described above, driving circuit 1000 according to the present embodiment controls gate voltage Vg in fourth region RG4 using comparator circuit 4 to suddenly increase gate voltage Vg at fourth slope SL4. This can increase temporal change rate dVce/dt of collector-emitter voltage Vce, thus reducing a switching loss in fourth region RG4, compared with the case of the driving circuit of the comparative example. Driving circuit 1000 of Embodiment 1 is characterized in that fourth slope SL4 in fourth region RG4 is greater than second slope SL2 in second region RG2.

Next, an operation of driving circuit 1000 at and after time t5 of FIG. 13 will be described. In the case of driving circuit 1000 of the present embodiment, since changes in collector current Ic and collector-emitter voltage Vce end at time t5, thereafter, the states thereof remain unchanged until input of the turn-off command.

Contrastingly, in the case of the driving circuit of the comparative example, the length of the mirror period depends on the magnitude of the output current of the driving circuit after gate voltage Vg has reached the mirror voltage at time t2. In the case of FIG. 13, the mirror period continues until time t6. When collector-emitter voltage Vce decreases to a certain value until time t3, collector-emitter voltage Vce then starts gently decreasing until time t6 at which the mirror period ends. This causes an increase in switching loss during a period from times t3 to t6.

As described above, in driving circuit 1000 according to Embodiment 1, gate voltage Vg during turn-on of power semiconductor element 8 is controlled separately in four time regions of first region RG1 to fourth region RG4, Specifically, in first region RG1, gate voltage Vg is controlled by voltage limiting circuit 1 to suddenly rise at first slope SL1 to approximately the threshold voltage. This can reduce a dead time, thus reducing a loss.

In the next second region RG2, gate voltage Vg is controlled by first change voltage generation circuit 2. When collector current Ic flowing through power semiconductor element 8 is small, gate voltage Vg reaches the mirror voltage in second region RG2. Since the change rate of the voltage generated by first change voltage generation circuit 2 is smaller than the change rate of the voltage generated by second change voltage generation circuit 3, change rate dVce/dt of collector-emitter voltage Vce by the recovery current can be reduced, thus reducing EMI.

In the next third region RG3, gate voltage Vg is controlled mainly by second change voltage generation circuit 3. When collector current Ic flowing through power semiconductor element 8 is small, gate voltage Vg has reached the mirror voltage in second region RG2, and accordingly, gate voltage Vg is constant in third region RG3.

In the next fourth region RG4, gate voltage Vg is controlled by the output voltage of comparator circuit 4. The change rate (corresponding to fourth slope SL4) of gate voltage Vg in fourth region RG4 is made greater than the voltage change rate (corresponding to second slope SL2) of gate voltage Vg in second region RG2 which is controlled by first change voltage generation circuit 2. This can increase change rate dVce/dt of collector-emitter voltage Vce, thus reducing a switching loss.

FIG. 14 is a timing chart for describing a second operation example of driving circuit 1000 for a power semiconductor element according to Embodiment 1. FIG. 14 shows a timing chart when the collector current is relatively large during turn-on operation of power semiconductor element 8. The waveforms shown in FIG. 14 correspond to the respective waveforms shown in FIG. 13. As in the case of FIG. 13, for the waveforms of gate voltage Vg, collector current Ie, and collector-emitter voltage Vce, the case of the present embodiment is indicated by the solid line, and the case of the comparative example is indicated by the dashed line. The comparative example shows a case of a driving circuit of the constant voltage driving type, in which gate voltage Vg of power semiconductor element 8 is not controlled separately in a plurality of time regions, or the constant current driving type.

A control operation of driving circuit 1000 and changes in gate voltage Vg from times t0 to time t1 of FIG. 14 are similar to those in the case of FIG. 13, and accordingly, description thereof will not be repeated.

Next, an operation of driving circuit 1000 from times t1 to t2 of FIG. 14 will be described. Limit voltage VL output from voltage limiting circuit 1, first change voltage V1 output from first change voltage generation circuit 2, second change voltage V2 output from second change voltage generation circuit 3, output voltage V3 of adder circuit 5, and the output of comparator circuit 4 are similar to those in the case of times t0 to t1.

Gate voltage Vg in the present embodiment increases at relatively gentle second slope SL2 based on voltage change rate dV1/dt of output voltage V1 of voltage limiting circuit 1 and first change voltage generation circuit 2 in second region RG2, as in the case of time t0 to time t1. When collector current Ic is relatively small as shown in FIG. 13, the mirror voltage is also small, and accordingly, gate voltage Vg reaches mirror voltage Vm at time t2. Contrastingly, when collector current Ic is relatively large as shown in FIG. 14, mirror voltage Vm is also relatively large, and accordingly, gate voltage Vg does not reach mirror voltage Vm at time t2. Changes in collector current Ic and collector-emitter voltage Vce from time t1 to time t2 are similar to those in the case of FIG. 13, and accordingly, description thereof will not be repeated.

Next, an operation of driving circuit 1000 from times t2 to t3 of FIG. 14 will be described. At and after time t2, second change voltage V2 output from second change voltage generation circuit 3 is greater than the sum of limit voltage VL and first change voltage V1 output respectively from voltage limiting circuit 1 and first change voltage generation circuit 2 before gate voltage Vg reaches mirror voltage Vm. As a result, output voltage V3 of adder circuit 5 changes from the resultant voltage VL+V1 generated in voltage limiting circuit 1 and first change voltage generation circuit 2 to the voltage based on the resultant voltage VL+V1 and second change voltage V2 generated in second change voltage generation circuit 3. Thus, the change rate of output voltage V3 of adder circuit 5 also changes from dV1/dt to a greater value.

Third region RG3 is a period after switch of the voltage change rate from dV1/dt to a greater change rate corresponding to third slope SL3 as described above. When collector current Ic is small as shown in FIG. 13, gate voltage Vg has reached mirror voltage Vm before third region RG3, and thus, gate voltage Vg remains unchanged in third region RG3. Contrastingly, when collector current Ie is large as shown in FIG. 14, gate voltage Vg has not reached mirror voltage Vm, and accordingly, gate voltage Vg is controlled at the voltage change rate corresponding to third slope SL3.

From times t0 to t2, change rate dIc/dt of collector current Ic of power semiconductor element 8 changes based on change rate dV1/dt of first change voltage V1 generated in first change voltage generation circuit 2. Contrastingly, from times t2 to t3, change rate dIc/dt is controlled mainly based on change rate dV2/dt of second change voltage V2 generated in second change voltage generation circuit 3. Since voltage change rate dV2/dt is greater than voltage change rate dV1/dt, change rate dIc/dt of collector current Ic is also greater at and after time t2 than at and before time t2. Contrastingly, in the case of the driving circuit of the comparative example, change rate dIc/dt of collector current Ic is constant from time t1 at which gate voltage Vg has reached threshold voltage Vth to time t3.

As described above, when collector current Ic is relatively large, driving circuit 1000 of the present embodiment changes change rate dIc/dt of collector current Ie in two stages until time t3 at which gate voltage Vg reaches mirror voltage Vm. In second region RG2 in which change rate dIc/dt of collector current Ic is smaller than in the case of the driving circuit of the comparative example, thus, a switching loss of power semiconductor element 8 is larger than in the case of the driving circuit of the comparative example. Contrastingly, when change rate dIc/dt of collector current Ic is made equal to that of the driving circuit of the comparative example in third region RG3, the switching loss of power semiconductor element 8 can be made equal to that of the driving circuit of the comparative example.

Next, an operation of driving circuit 1000 from time t3 to time t4 of FIG. 14 will be described. In the case of FIG. 14, gate voltage Vg reaches mirror voltage Vm at time t3 in third region RG3 in which gate voltage Vg is controlled mainly by second change voltage generation circuit 3. Also in the case of the driving circuit of the comparative example, gate voltage Vg reaches mirror voltage Vm at time t3. Since the recovery current flows as gate voltage Vg reaches mirror voltage Vm, collector current Ic changes. Herein, in the example shown in FIG. 14, the change rate of gate voltage Vg in driving circuit 1000 of the present embodiment is the same as the change rate of gate voltage Vg in the driving circuit of the comparative example, and thus, change rate dIc/dt of collector current Ic is also the same between the present embodiment and the comparative example. The change rate of gate voltage Vg in third region RG3 does not need to be the same between the present embodiment and the comparative example.

Next, an operation of driving circuit 1000 from time t4 to time t5 of FIG. 14 will be described. At time t4, output voltage V2 of second change voltage generation circuit 3 which is input to comparator circuit 4 reaches comparative voltage VC of comparator circuit 4. As a result, the determination result of comparator circuit 4 changes from low to high. When the determination result of comparator circuit 4 becomes high, a current is injected into the gate terminal of power semiconductor element 8, and accordingly, gate voltage Vg suddenly rises at fourth slope SL4.

Fourth region RG4 is a region in which gate voltage Vg changes at fourth slope SL4 based on changes in the output voltage of comparator circuit 4. In other words, fourth region RG4 is a period from an end of the mirror period of gate voltage Vg (time t4) to gate voltage Vg reaching the supply voltage of driving circuit 1000 (time t5). Contrastingly, also at and after time t5, gate voltage Vg of the driving circuit of the comparative example has been in the mirror period until time t6, causing a loss due to switching during the mirror period. Such an operation of the driving circuit is the same as that of the case where collector current Ic is relatively small as shown in FIG. 13.

As described above, driving circuit 1000 according to the present embodiment controls gate voltage Vg in fourth region RG4 using comparator circuit 4 and suddenly increases gate voltage Vg at fourth slope SL4. Consequently, change rate dVce/dt of collector-emitter voltage Vce can be increased, and thus, a switching loss in fourth region RG4 can be reduced compared with the case of the driving circuit of the comparative example. Also, driving circuit 1000 of Embodiment 1 is characterized in that the change rate (i.e., fourth slope SL4) of gate voltage Vg in fourth region RG4 is made greater than the change rate (i.e., second slope SL2) of gate voltage Vg in second region RG2.

Next, an operation of driving circuit 1000 at and after time t5 of FIG. 14 will be described. In the case of driving circuit 1000 of the present embodiment, since changes in collector current Ic and collector-emitter voltage Vce end at time t5, thereafter, the states thereof remain unchanged until input of the turn-off command.

Contrastingly, in the case of the driving circuit of the comparative example, the length of the mirror period of gate voltage Vg depends on the magnitude of the output current of driving circuit 1000 after reaching mirror voltage at time t2. In the case of FIG. 13, the mirror period continues until time t6. When collector-emitter voltage Vce decreases to a certain value until time t3, collector-emitter voltage Vce then starts decreasing gently until time t6 at which the mirror period ends. In the period from times t3 to t6, thus, a switching loss of power semiconductor element 8 controlled by the driving circuit of the comparative example is greater than in the present embodiment.

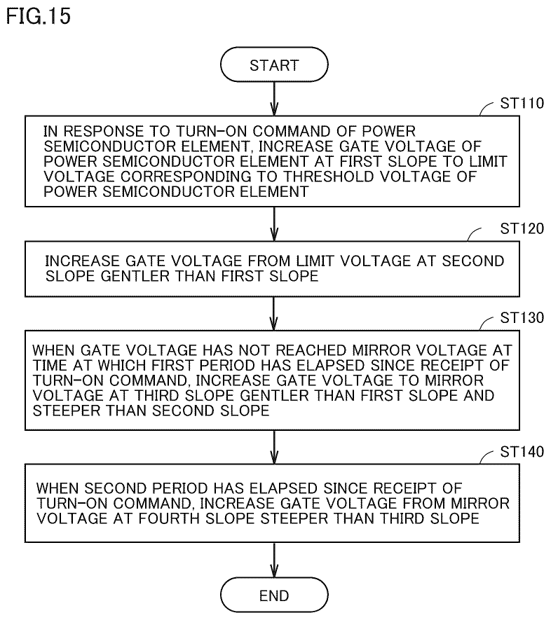

FIG. 15 is a flowchart showing a control procedure during turn-on of power semiconductor element 8 by driving circuit 1000 of Embodiment 1. The description given so far will be summarized with reference to FIG. 15.

In step ST110 of FIG. 15, driving circuit 1000 increases gate voltage Vg of power semiconductor element 8 at first slope SL1 to limit voltage VL corresponding to threshold voltage Vth of power semiconductor element 8 in first time region RG1, in response to the turn-on command of power semiconductor element 8.

In the next step ST120, driving circuit 1000 increases gate voltage Vg from limit voltage VL at second slope SL2 gentler than first slope SL1 in second time region RG2 following first time region RG1.

In the next step ST130, when gate voltage Vg has not reached mirror voltage Vm at a time (time t2 of FIG. 13, time t3 of FIG. 14) at which the first period has elapsed since the receipt of the turn-on command, driving circuit 1000 increases gate voltage Vg to mirror voltage Vm at third slope SL3 gentler than first slope SL1 and steeper than second slope SL2 in third time region RG3 following second time region RG2. In Embodiment 1, irrespective of whether gate voltage Vg has reached mirror voltage Vm, driving circuit 1000 increases the increase rate of the voltage supplied to the gate terminal of power semiconductor element 8 when the first period described above has elapsed since the receipt of the turn-on command. However, if gate voltage Vg has entered the mirror period before a lapse of the first period, the influence of an increase in voltage increase rate does not appear as a change in gate voltage.

In the next step ST140, driving circuit 1000 increases the gate voltage from the mirror voltage at fourth slope SL4 steeper than third slope SL3 in fourth time region RG4. Finally, gate voltage Vg increases to the supply voltage supplied to driving circuit 1000.

### [Effects of Embodiment 1]

As described above, in driving circuit 1000 according to Embodiment 1, gate voltage Vg during turn-on of power semiconductor element 8 is controlled separately in four time regions of first region RG1 to fourth region RG4. Specifically, in first region RG1, gate voltage Vg is controlled by voltage limiting circuit 1, and thus suddenly rises to approximately the threshold voltage at first slope SL1. This can reduce a dead time, thus reducing a loss.

In the next second region RG2, gate voltage Vg is controlled by first change voltage generation circuit 2. When collector current Ic flowing through power semiconductor element 8 is small, gate voltage Vg reaches the mirror voltage in second region RG2. Since the change rate of the voltage generated by first change voltage generation circuit 2 is smaller than the change rate of the voltage generated by second change voltage generation circuit 3, change rate dVce/dt of collector-emitter voltage Vce by the recovery current can be reduced, thus reducing EMI.

In the next third region RG3, when collector current Ic flowing through power semiconductor element 8 is relatively large, gate voltage Vg reaches the mirror voltage in third region RG3. In this case, before gate voltage Vg reaches the mirror voltage, gate voltage Vg is increased at third slope SL3 mainly using second change voltage generation circuit 3. Since third slope SL3 is greater than second slope SL2 that is the change rate of gate voltage Vg in second region RG2, change rate dIc/dt of collector current Ic can be increased, thus suppressing an increase in loss.

In the next fourth region RG4, gate voltage Vg is controlled by the output voltage of comparator circuit 4. The change rate of gate voltage Vg at this time is made greater than the voltage change rate in second region RG2 which is controlled by second change voltage generation circuit 3. This can increase change rate dVce/dt of collector-emitter voltage Vce, thus reducing a switching loss.

### [Implementations of Driving Circuit]

Implementations of driving circuit 1000 described above will be described below while giving some examples.

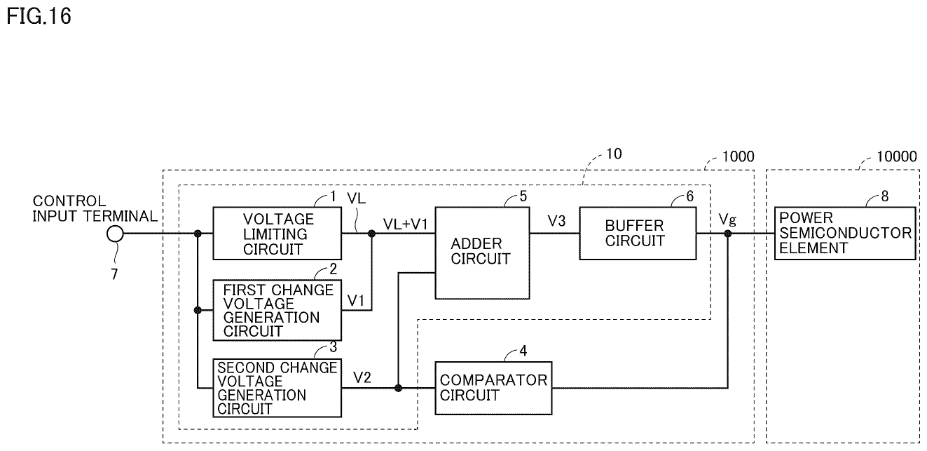

FIG. 16 shows an example implementation of driving circuit 1000 of Embodiment 1. As shown in FIG. 16, driving circuit 1000 of Embodiment 1 can be combined with a power module 10000 formed of power semiconductor element 8. As described above, driving circuit 1000 of Embodiment 1 may be configured separately from power module 10000 formed of power semiconductor element 8.

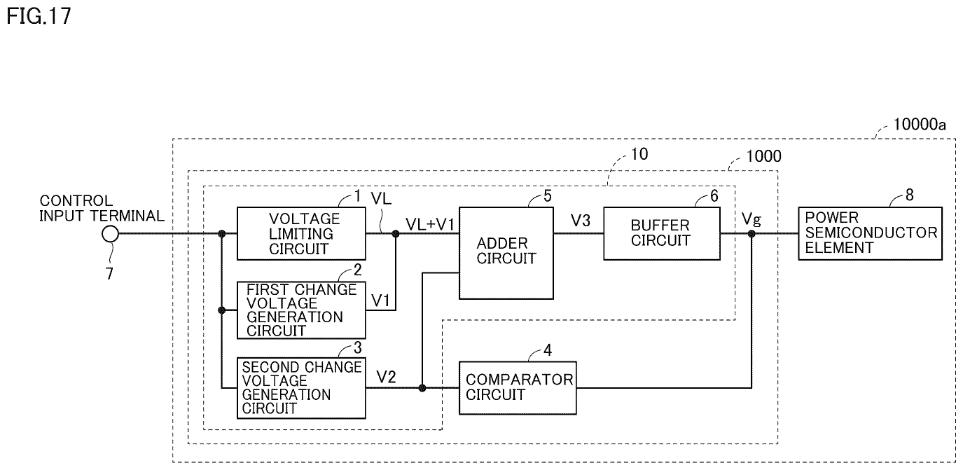

FIG. 17 shows a modification of the implementation of FIG. 16. As shown in FIG. 17, a power module 10000a formed of power semiconductor element 8 may include driving circuit 1000 of Embodiment 1. In other words, power module 10000a includes driving circuit 1000 of Embodiment 1 and power semiconductor element 8.

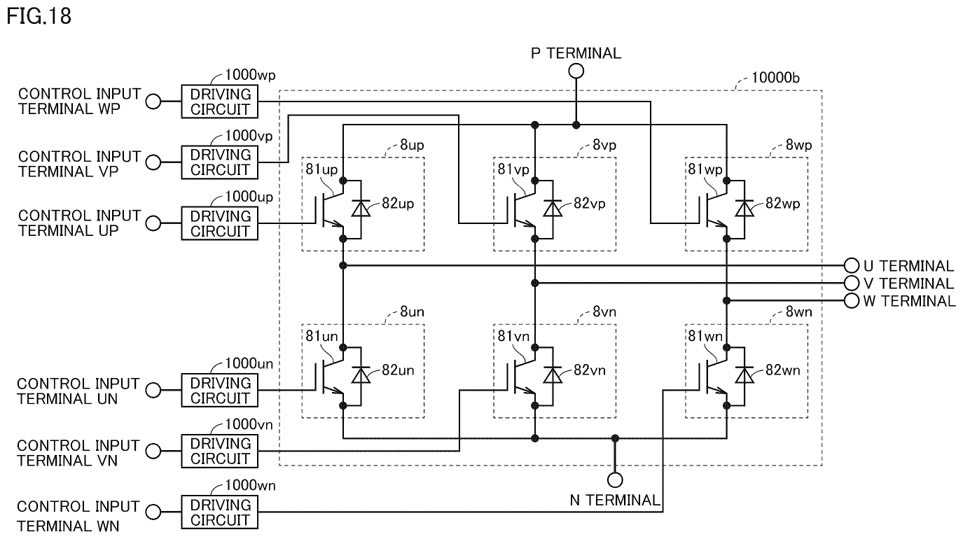

FIG. 18 shows another example of the implementation of driving circuit 1000 of Embodiment 1. FIG. 18 shows a more specific implementation example of driving circuit 1000 combined with a three-phase AC power module 10000b. In other words, six driving circuits 1000un, 1000vn, 1000wn, 1000up, 1000vp, 1000wp are implemented to drive power module 10000b composed of six power semiconductor elements. The number of power semiconductor elements included in one power module is not particularly limited. In other words, the power module may have, for example, the 1 in 1, 2 in 1, 6 in 1, or multi-parallel configuration.

FIG. 18 shows power module 10000b of 6 in 1 configuration. Power module 10000b includes power semiconductor elements 8up, 8vp, 8wp, 8un, 8vn, 8wn. Each power semiconductor element 8 includes an IGBT 81 (81up, 81vp, 81wp, 81un, 81vn, 81wn) and a diode 82 (82up, 82vp, 82wp, 82un, 82vn, 82wn) connected in anti-parallel with its corresponding IGBT.

Specifically, power semiconductor elements 8up, 8un for the U phase are connected in series between a P terminal and a Q terminal. A node of connection between power semiconductor elements 8up, 8un is connected to a U terminal, Gates of power semiconductor elements 8up, 8un are connected to driving circuits 1000up, 1000un, respectively. Driving circuits 1000up, 1000un are provided with control input terminals UP, UN, respectively. The same is true for the V phase and the W phase, and it is only required to read u (or U) as v, w (V, W) in the above description.

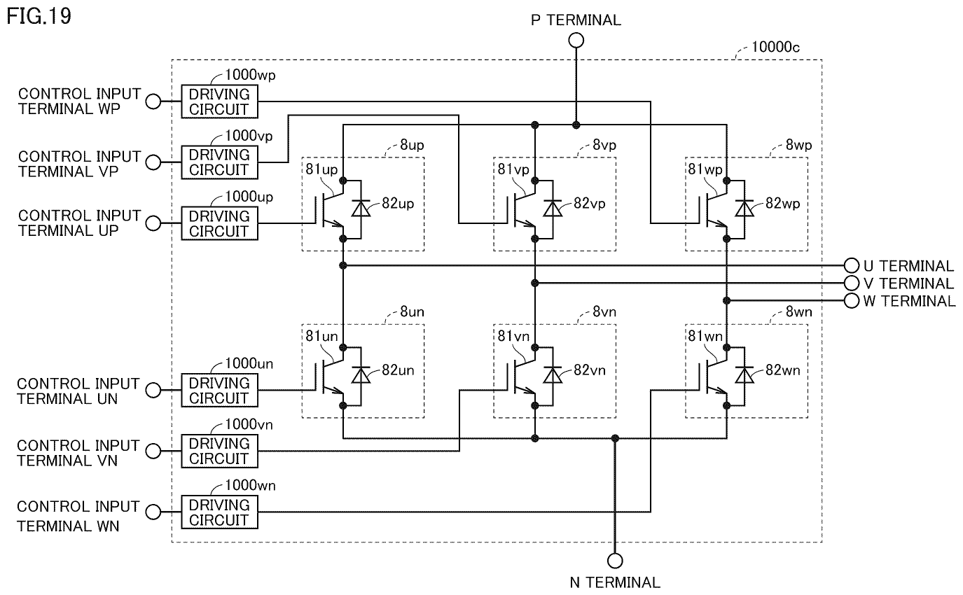

FIG. 19 shows a modification of the implementation of FIG. 18. As shown in FIG. 19, a power module 100000 composed of power semiconductor elements 8up, 8vp, 8wp, Sun, 8vn, 8wn may include six driving circuits 1000un, 1000vn, 1000wn, 1000up, 1000vp, 1000wp. In other words, power module 10000c includes six driving circuits 1000un, 1000vn, 1000wn, 1000up, 1000vp, 1000wp of Embodiment 1, and power semiconductor elements Sup, 8vp, 8wp, 8un, 8vn, 8wn corresponding to the respective driving circuits.

As in the case of FIG. 18, the number of power semiconductor elements included in one power module is not particularly limited. In other words, the power module may have the 1 in 1, 2 in 1, 6 in 1, multi-parallel, or any other configuration. As many driving circuits as power semiconductor elements are included in one power module.

### Embodiment 2

A driving circuit 2000 for a power semiconductor element according to Embodiment 2 is different from driving circuit 1000 of Embodiment 1 in that it further includes a mirror voltage detection circuit 9, which detects a mirror voltage. Description will be given below in detail with reference to the drawings.

### [Configuration of Driving Circuit]

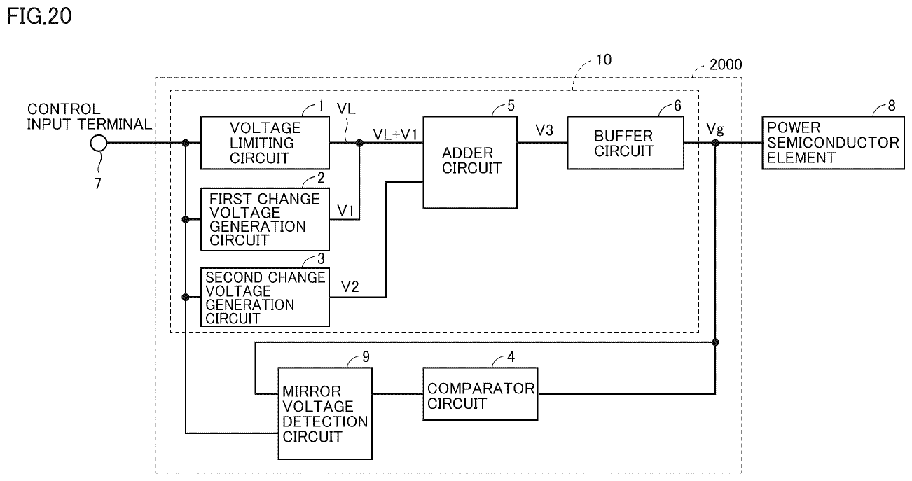

FIG. 20 shows a configuration of driving circuit 2000 for a power semiconductor element according to Embodiment 2. Similarly to driving circuit 1000 of Embodiment 1, driving circuit 2000 of FIG. 20 generates gate voltage Vg for controlling switching of power semiconductor element 8 according to a control signal input to control input terminal 7. More specifically, driving circuit 1000 controls voltage changes of gate voltage Vg during turn-on operation of power semiconductor element 8 in four time regions of first region ROI to fourth region RG4 in order. In Embodiment 2, second region RG2 may directly shift to fourth region RG4 without third region RG3 provided.

As shown in FIG. 20, driving circuit 2000 includes voltage limiting circuit 1, first change voltage generation circuit 2, second change voltage generation circuit 3, comparator circuit 4, adder circuit 5, and buffer circuit 6 as the same components as those of driving circuit 1000 of Embodiment 1. The functions of these circuits are similar to those in Embodiment 1 except for comparator circuit 4. To describe briefly, voltage limiting circuit 1 controls voltage changes of gate voltage Vg in the first region. First change voltage generation circuit 2 controls voltage changes of gate voltage Vg in the second region. Second change voltage generation circuit 3 controls voltage changes of gate voltage Vg in the third region. Comparator circuit 4 controls voltage changes of gate voltage Vg in the fourth region. Adder circuit 5 outputs currents and voltages output from voltage limiting circuit 1 and first change voltage generation circuit 2 in second region RG2. Adder circuit 5 adds an output current of second change voltage generation circuit 3 to output currents of voltage limiting circuit 1 and first change voltage generation circuit 2 in third region RG3. Buffer circuit 6 transfers an output voltage of adder circuit 5 to the gate terminal of power semiconductor element 8, thereby generating the gate voltage of power semiconductor element 8.

Driving circuit 2000 includes mirror voltage detection circuit 9 as a new component. Mirror voltage detection circuit 9 detects a timing at which gate voltage Vg has reached the mirror voltage, and outputs a detection result to comparator circuit 4. Comparator circuit 4 compares the detection result of mirror voltage detection circuit 9 with the output voltage (i.e., comparative voltage VC) of comparative voltage source 42, and outputs a comparison result. Specifically, when the output of mirror voltage detection circuit 9 is activated to the high level, a high-level output signal of mirror voltage detection circuit 9 is greater than comparative voltage VC. In this case, thus, comparator circuit 4 outputs the supply voltage of driving circuit 2000 as the high-level signal to the gate terminal of power semiconductor element 8.

The problem with driving circuit 1000 of Embodiment 1 which is not provided with mirror voltage detection circuit 9 is as follows. In other words, in driving circuit 1000 of Embodiment 1, a timing of shift to the fourth region is controlled according to the setting value of the comparative voltage of comparator circuit 4. More specifically, comparator circuit 4 compares comparative voltage VC (i.e., a voltage value of comparative voltage source 42) with output voltage V2 of second change voltage generation circuit 3 and, when output voltage V2 becomes greater than or equal to comparative voltage VC, shifts to the fourth region to change the voltage change rate of gate voltage Vg. As described above, since control of the gate voltage in the fourth region is started at the timing dependent on the change rate of voltage V2 generated in second change voltage generation circuit 3, the timing to start controlling the gate voltage in the fourth region remains unchanged even when the magnitude of collector current Ic of the power semiconductor element changes and the magnitude of the mirror voltage and the length of the mirror period change. In driving circuit 1000 of Embodiment 1, thus, the period of time from the gate voltage reaching the mirror voltage to start of control of the gate voltage in the fourth region becomes longer as collector current Ic decreases. This reduces the effect of reducing a switching loss by controlling the change rate of the gate voltage in the fourth region and increasing change rate dVce/dt of collector-emitter voltage Vce. Driving circuit 2000 of Embodiment 2 solves the problem described above.

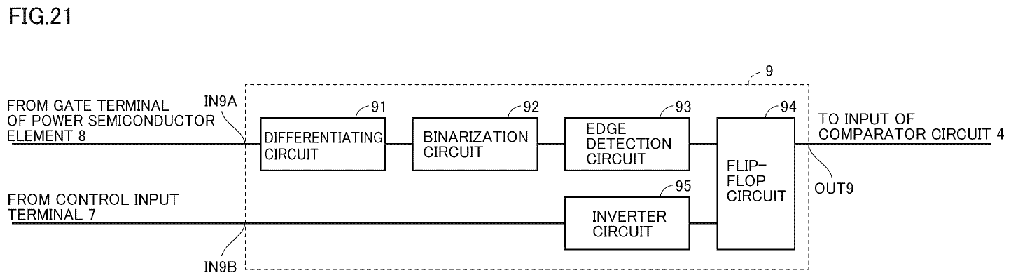

FIG. 21 shows an example configuration of mirror voltage detection circuit 9. As shown in FIG. 21, mirror voltage detection circuit 9 includes a differentiating circuit 91, a binarization circuit 92, an edge detection circuit 93, a flip-flop circuit 94, and an inverter circuit 95.

Differentiating circuit 91, binarization circuit 92, and edge detection circuit 93 are connected in the stated order between an input node IN9A and an S input of flip-flop circuit 94. Input node IN9A is connected to the gate terminal of power semiconductor element 8. Inverter circuit 95 is connected between an input node IN9B and an R input of flip-flop circuit 94. Input node IN9B is connected to control input terminal 7. A Q output of flip-flop circuit 94 is connected via an output node OUT9 to input node IN4 of comparator circuit 4.

Mirror voltage detection circuit 9 detects a mirror voltage generated in a gate signal Vg of power semiconductor element 8 by differentiating circuit 91, binarization circuit 92, and edge detection circuit 93, and holds the state detected by flip-flop circuit 94. Also, inverter circuit 95 of mirror voltage detection circuit 9 inverts a control signal input from control input terminal 7. The inverted control signal is used for resetting flip-flop circuit 94. Thus, mirror voltage detection circuit 9 detects a mirror voltage when the control signal is the high level, then holds a detection result, and resets the held detection result as the control signal enters the low level.

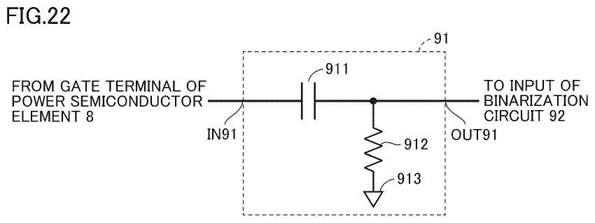

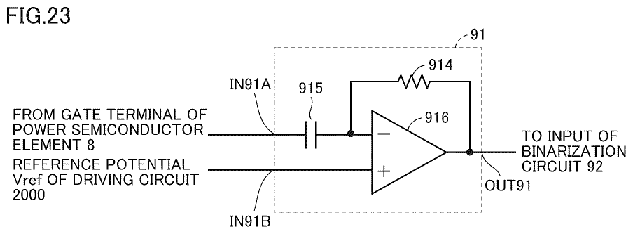

Each of FIGS. 22 and 23 shows an example configuration of differentiating circuit 91 of FIG. 21. Differentiating circuit 91 differentiates gate voltage Vg of power semiconductor element 8 and outputs a differentiated signal to binarization circuit 92.

In the example configuration of FIG. 22, differentiating circuit 91 includes a capacitive element 911 and a resistive element 912. Capacitive element 911 is connected between an input node IN91 and an output node OUT91. Resistive element 912 is connected between output node OUT91 and a reference node 913 to which reference potential Vref is applied. Input node IN91 is connected to the gate terminal of power semiconductor element 8, and output node OUT91 is connected to an input of binarization circuit 92.

In the example configuration of FIG. 23, differentiating circuit 91 includes a resistive element 914, a capacitive element 915, and an operational amplifier 916. Resistive element 914 is connected between an inverting input terminal of operational amplifier 916 and an output terminal of operational amplifier 916. Capacitive element 915 is connected between the inverting input terminal of operational amplifier 916 and input node IN91A. A reference potential Vref of driving circuit 2000 is input to a non-inverting input terminal of operational amplifier 916 via input node IN91B. The output terminal of operational amplifier 916 is connected to the input of binarization circuit 92 via output node OUT91.

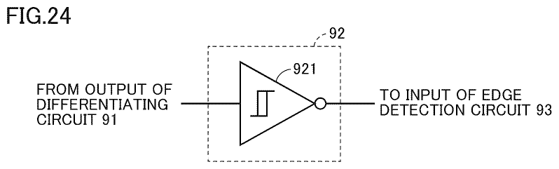

FIG. 24 shows an example configuration of binarization circuit 92. Binarization circuit 92 converts an output of differentiating circuit 91 into a binary value of high level and low level and outputs a binary-converted signal to edge detection circuit 93. As shown in FIG. 24, edge detection circuit 93 is formed of an inverted Schmitt-trigger circuit 921 (also referred to as Schmitt-trigger inverter or hysteresis inverter).

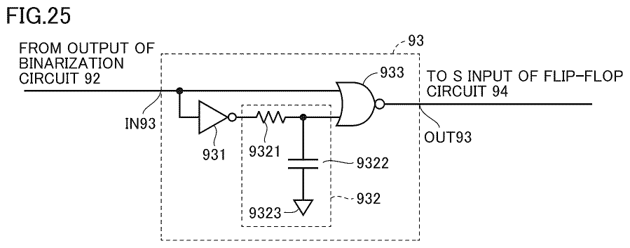

FIG. 25 shows an example configuration of edge detection circuit 93. Edge detection circuit 93 detects a rising edge or a falling edge of an output signal of binarization circuit 92 and outputs a detection result. Which of the rising edge or the falling edge is detected can be changed depending on the polarity of binarization circuit 92 or the polarity detected by flip-flop circuit 94, and an edge suitable for detecting that gate voltage Vg has reached the mirror voltage is selected.

As shown in FIG. 25, edge detection circuit 93 includes an inverter circuit (inverter) 931, a delay circuit 932, and a NOR circuit 933. Delay circuit 932 includes a resistive element 9321 and a capacitive element 9322 by way of example. An input node IN93 of edge detection circuit 93 is connected to a first input terminal of NOR circuit 933 and is connected to a second input terminal of NOR circuit 933 via inverter circuit 931 and delay circuit 932 in order. Resistive element 9321 of delay circuit 932 is connected between an output terminal of inverter circuit 931 and the second input terminal of NOR circuit 933. Capacitive element 9322 of delay circuit 932 is connected between the second input terminal of NOR circuit 933 and a reference node 9323 to which reference potential Vref is applied. Input node IN93 of edge detection circuit 93 is connected to an output of binarization circuit 92. An output terminal of NOR circuit 933 is connected via an output node OUT93 to an S input node of flip-flop circuit 94.

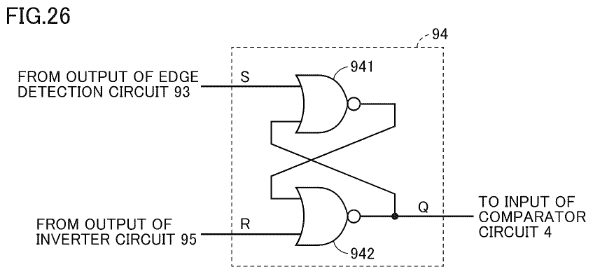

FIG. 26 shows an example configuration of flip-flop circuit 94, Flip-flop circuit 94 includes two NOR circuits 941, 942. NOR circuit 941 has a first input terminal connected as a set terminal S to output node OUT93 of edge detection circuit 93. NOR circuit 941 has a second input terminal connected to an output terminal of NOR circuit 942. NOR circuit 941 has an output terminal connected to the first input terminal of NOR circuit 942. NOR circuit 942 has a second input terminal connected as a reset terminal R to an output of inverter circuit 95. NOR circuit 942 has an output terminal connected as an output terminal Q of flip-flop circuit 94 to an input of comparator circuit 4.

Flip-flop circuit 94 is activated as a signal detected by edge detection circuit 93 is input to set terminal S and is deactivated as a control signal inverted by inverter circuit 95 is input to reset terminal R.

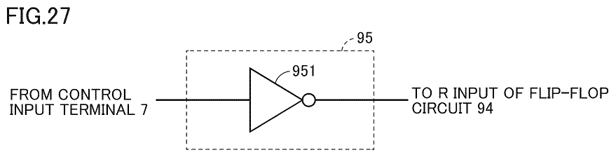

FIG. 27 shows an example configuration of inverter circuit 95. Inverter circuit 95 includes a NOT circuit 951. Inverter circuit 95 inverts the polarity of a control signal input from control input terminal 7 and outputs the inverted control signal to reset terminal R of flip-flop circuit 94. Consequently, the state held in flip-flop circuit 94 is reset.

### [Operation of Driving Circuit]

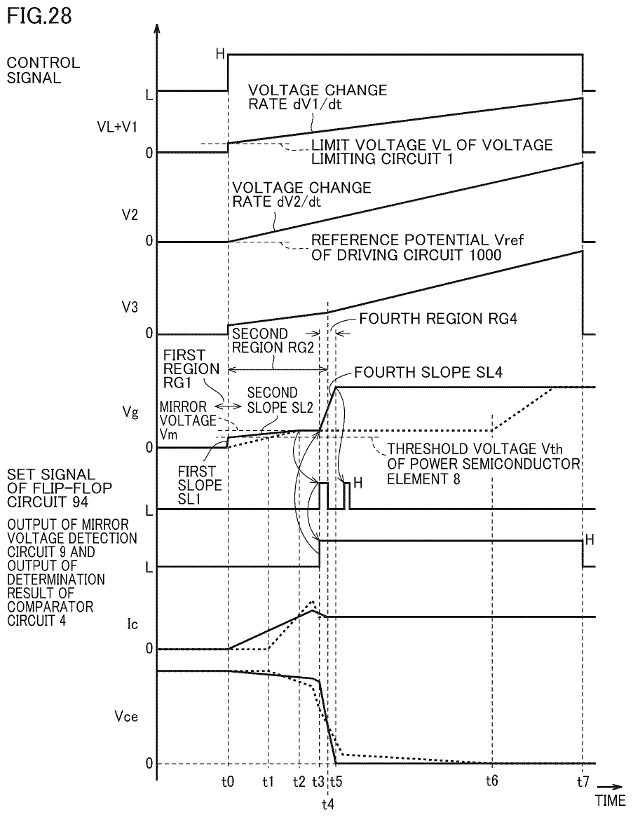

FIG. 28 is a timing chart for describing an operation example of driving circuit 2000 for a power semiconductor according to Embodiment 2. FIG. 28 shows a timing chart when collector current Ic is relatively small during turn-on operation of power semiconductor element 8. Waveforms of a control signal input to control input terminal 7, the sum (VL+V1) of limit voltage VL output from voltage limiting circuit 1 and first change voltage V1 output from first change voltage generation circuit 2, second change voltage V2 output from second change voltage generation circuit 3, output voltage V3 of adder circuit 5, gate voltage Vg of power semiconductor element 8, a set signal of flip-flop circuit 94, an output of mirror voltage detection circuit 9 and an output of a determination result of comparator circuit 4, and collector current Ic and collector-emitter voltage Vce of power semiconductor element 8 are shown in order from the top of FIG. 28. For the waveforms of gate voltage Vg, collector current Ic, and collector-emitter voltage Vce, the case of the present embodiment is indicated by the solid line, and the case of the comparative example is indicated by the dashed line. The comparative example shows the case of a driving circuit of the constant voltage driving type, in which gate voltage Vg of power semiconductor element 8 is not controlled separately in a plurality of time regions, or the constant current driving type.

Driving circuit 2000 for a power semiconductor element according to Embodiment 2 is characterized in that collector current Ic and collector-emitter voltage Vce of power semiconductor element 8 are controlled by a different method depending on whether collector current Ic is relatively small or relatively large, similarly to driving circuit 1000 of Embodiment 1. In the following description of an operation of driving circuit 2000 of Embodiment 2, description will be given of a difference from an operation of driving circuit 1000 of Embodiment 1 shown in FIG. 13 when a collector current is relatively small.

Description will be given below in chronological order. First, an operation of driving circuit 2000 at time to of FIG. 28 will be described.

At time t0, as in driving circuit 1000 of Embodiment 1, when the control signal of control input terminal 7 changes from low to high as the turn-on operation command, voltage limiting circuit 1, first change voltage generation circuit 2, and second change voltage generation circuit 3 start operating. Voltage changes of gate voltage Vg in first region RG1 in the vicinity of time t0 are controlled by voltage limiting circuit 1. As in Embodiment 1, voltage limiting circuit 1 suddenly increases gate voltage Vg to approximately threshold voltage Vth (corresponding to limit voltage VL) at first slope SL1 in first region RG1. This can reduce a dead time, thus reducing a loss.

In FIG. 28, an operation of driving circuit 2000 from time t0 to time t2 is almost the same as the operation of driving circuit 1000 of Embodiment 1 shown in FIG. 13. In other words, the waveforms of the resultant voltage VL+V1 of outputs of voltage limiting circuit 1 and first change voltage generation circuit 2, output voltage V2 of second change voltage generation circuit 3, output voltage V3 of adder circuit 5, collector current Ic, and collector-emitter voltage Vce are the same as those in the case of driving circuit 1000 of Embodiment 1 shown in FIG. 13.

Flip-flop circuit 94 is deactivated because gate voltage Vg has not reached mirror voltage Vm until time t2. Thus, an output of mirror voltage detection circuit 9 is also the low (L) level.

Next, an operation of driving circuit 2000 from times t2 to t5 of FIG. 28 will be described.

At time t2, gate voltage Vg reaches mirror voltage Vm. When gate voltage Vg reaches the mirror voltage, mirror voltage detection circuit 9 operates and detects a timing at which gate voltage Vg has reached the mirror voltage by differentiating circuit 91, binarization circuit 92, and edge detection circuit 93. A delay time occurs in timing detection by differentiating circuit 91, binarization circuit 92, and edge detection circuit 93, and thus, a set signal of flip-flop circuit 94 changes from low to high at time t3 a constant period of time after time t2.

The delay time that occurs in timing detection by differentiating circuit 91, binarization circuit 92, and edge detection circuit 93 can be designed as appropriate as a design parameter by a designer. Thus, an interval between the timing at which gate voltage Vg has reached mirror voltage Vm and the timing at which a change rate of gate voltage Vg is adjusted by comparator circuit 4, which is the next operation, can also be designed as appropriate by the designer.

When the set signal of flip-flop circuit 94 changes from low to high at time t3, an output of mirror voltage detection circuit 9 changes from low to high, and that state is held. Further, when the output of mirror voltage detection circuit 9 changes from low to high at time t3, the determination result of comparator circuit 4 also changes from low to high. When the determination result of comparator circuit 4 changes to high, a current is injected into the gate terminal of power semiconductor element 8, and accordingly, gate voltage Vg suddenly increases at fourth slope SL4. In other words, in the example of FIG. 28, second region RG2 directly shifts to fourth region RG4 without third region RG3 in between. As gate voltage Vg is suddenly increased at fourth slope SL4, change rate dVce/dt of collector-emitter voltage Vce can be increased, thus reducing a switching loss.

Between time t2 and time t5, gate voltage Vg controlled by the driving circuit of the comparative example is still in the mirror period, and a loss is caused by switching during the mirror period. In the case of driving circuit 1000 of Embodiment 1 shown in FIG. 13, the timing of switch of an output of comparator circuit 4 from low to high depends on the result of comparison between the comparative voltage of comparator circuit 4, which is set as appropriate, and output voltage V2 of second change voltage generation circuit 3. Depending on the setting of the comparative voltage, thus, the timing of switch of the output of comparator circuit 4 from low to high delays from the timing in the case of driving circuit 2000 of Embodiment 2.

Driving circuit 2000 of Embodiment 2 can detect the timing at which gate voltage Vg has reached mirror voltage Vm by mirror voltage detection circuit 9 even when the mirror period of gate voltage Vg has changed according to the value of collector current Ic, and operate comparator circuit 4 according to a detection result, Contrastingly, in the case of driving circuit 1000 of Embodiment 1, the timing at which comparator circuit 4 operates delays more as mirror voltage Vm becomes smaller, and accordingly, the timing to control collector-emitter voltage Vce delays. Driving circuit 2000 of Embodiment 2 can thus have a smaller loss than driving circuit 1000 of Embodiment 1.

The set signal of flip-flop circuit 94 changes to high at time (3, and then, falls from high to low at time t4 according to an operation of edge detection circuit 93. The period in which edge detection circuit 93 maintains the high level can be designed as appropriate by the designer. Thus, the period in which edge detection circuit 93 maintains the high level can be set as appropriate according to the length for which flip-flop circuit 94 can operate and the frequency at which power semiconductor element 8 is operated.

At time t5, when gate voltage Vg reaches a supply voltage of driving circuit 2000, edge detection circuit 93 of mirror voltage detection circuit 9 changes from low to high. However, an output of flip-flop circuit 94, that is, an output of mirror voltage detection circuit 9 has held the high state since time t3, and accordingly, such output states remain unchanged.

At a time t7, when the control signal changes from high to low, the turn-off operation starts, and all of output voltage V1 of voltage limiting circuit 1 and first change voltage generation circuit 2, output voltage V2 of second change voltage generation circuit 3, and output voltage V3 of adder circuit 5 decrease to zero.

In mirror voltage detection circuit 9, also, the reset signal of flip-flop circuit 94 changes to the high level when the control signal changes from high to low. Consequently, the state held by flip-flop circuit 94 is reset. In other words, both the output of mirror voltage detection circuit 9 and the determination result of comparator circuit 4 change from high to low. This ends the injection of a current into the gate terminal of power semiconductor element 8.

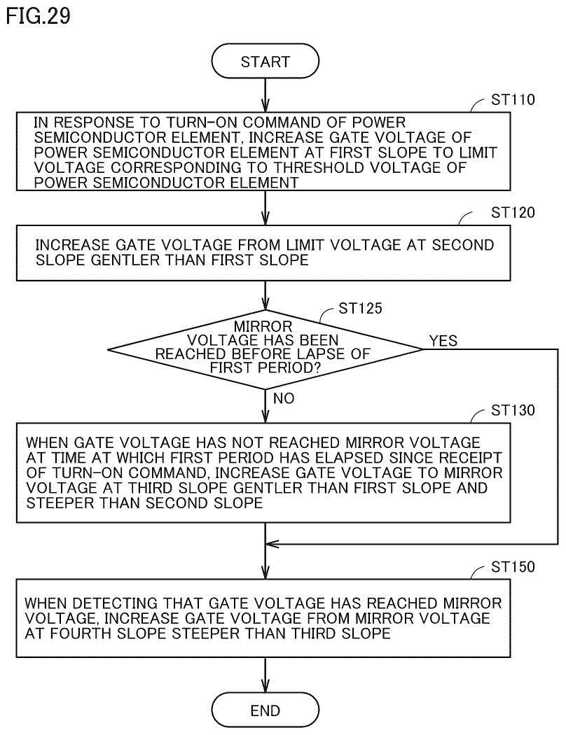

FIG. 29 is a flowchart showing a control procedure during turn-on of power semiconductor element 8 by driving circuit 2000 of Embodiment 2. Description given so far will be summarized with reference to FIG. 29.

In step ST110 of FIG. 29, driving circuit 2000 increases gate voltage Vg of power semiconductor element 8 at first slope SL1 to limit voltage VL corresponding to threshold voltage Vth of power semiconductor element 8 in first time region RG1, in response to the turn-on command of power semiconductor element 8.

In the next step ST120, driving circuit 2000 increases gate voltage Vg from limit voltage VL at second slope SL2 gentler than first slope SL1 in second time region RG2 following first time region RG1.

Subsequently, when mirror voltage detection circuit 9 detects that gate voltage Vg has reached mirror voltage Vm (YES in step ST125), driving circuit 2000 moves the process to step ST150. In step ST150, driving circuit 2000 increases the gate voltage from the mirror voltage at fourth slope SL4 steeper than third slope SL3. Finally, gate voltage Vg increases to the supply voltage supplied to driving circuit 2000.

Contrastingly, when mirror voltage detection circuit 9 does not detect that gate voltage Vg has reached mirror voltage Vm at the time at which the first period has elapsed since the receipt of the turn-on command (NO in step ST125), the process proceeds to step ST130.

In step ST130, driving circuit 2000 increases gate voltage Vg to mirror voltage Vm at third slope SL3 gentler than first slope SL1 and steeper than second slope SL2 in third time region RG3 following second time region RG2. Subsequently, step ST150 is performed.

### [Effects of Embodiment 2]

As described above, driving circuit 2000 of Embodiment 2 basically controls gate voltage Vg during turn-on of power semiconductor element 8 separately in four time regions of first region RG1 to fourth region RG4, as in the case of driving circuit 1000 of Embodiment 1. Specifically, in first region RG1, gate voltage Vg is controlled by voltage limiting circuit 1, and thus, suddenly rises at first slope SL1 to approximately the threshold voltage. This can reduce a dead time, thus reducing a loss.

In the next second region RG2, gate voltage Vg is controlled by first change voltage generation circuit 2. When collector current Ic flowing through power semiconductor element 8 is small, in second region RG2, gate voltage Vg reaches the mirror voltage. Since the change rate (corresponding to second slope SL2) of the voltage generated by first change voltage generation circuit 2 is smaller than the change rate of the voltage generated by second change voltage generation circuit 3, change rate dVce/dt of collector-emitter voltage Vce by the recovery current can be reduced, thus reducing EMI.

In the next third region RG3, when collector current Ic flowing through power semiconductor element 8 is relatively large, control is performed. When collector voltage Ic is relatively large, gate voltage Vg reaches the mirror voltage in the middle of third region RG3. In this case, before gate voltage Vg reaches the mirror voltage, gate voltage Vg is controlled to increase at third slope SL3 steeper than second slope SL2 using second change voltage generation circuit 3. Consequently, change rate dIc/dt of collector current Ic can be increased, thus suppressing an increase in loss.

Control in the next fourth region RG4 is performed based on mirror voltage detection circuit 9 detecting the timing at which gate voltage Vg reaches mirror voltage Vm. As comparator circuit 4 operates in response to the detection of the timing at which mirror voltage Vm has been reached, change rate dVce/dt of collector-emitter voltage Vce can be increased, thus reducing a switching loss. Comparator circuit 4 operates based on a detection result of mirror voltage detection circuit 9, and thus can have a reduced switching loss compared with the case of driving circuit 1000 of Embodiment 1 in which the timing at which comparator circuit 4 operates delays more as the mirror voltage becomes smaller.

### [Implementations of Driving Circuit of Embodiment 2]

The implementations described with reference to FIGS. 16 to 19 of Embodiment 1 are also applicable to driving circuit 2000 of Embodiment 2.

It should be understood that the embodiments disclosed herein have been presented for the purpose of illustration and non-restrictive in every respect. It is intended that the scope of the present application is defined by claims, not only by the above description, and encompasses all modifications and variations equivalent in meaning and scope to the claims.

### REFERENCE SIGNS LIST

1 voltage limiting circuit; 2 first change voltage generation circuit; 3 second change voltage generation circuit; 4 comparator circuit (second gate voltage control circuit); 5 adder circuit; 6 buffer circuit; 7, UN, UP control input terminal; 8 power semiconductor element; 9 mirror voltage detection circuit; 10 first gate voltage control circuit; 11 Zener diode; 41 comparator; 42 comparative voltage source; 61, 63 bipolar transistor; 65, 916 operational amplifier; 82 freewheel diode; 91 differentiating circuit; 92 binarization circuit; 93 edge detection circuit; 94 flip-flop circuit; 95, 931 inverter circuit; 921 inverted Schmitt-trigger circuit; 932 delay circuit; 1000, 2000 driving circuit; 10000, 10000a, 10000b, 10000c power module; RG1 to RG4 first time region to fourth time region; SL1 to SL4 first slope to fourth slope; VL limit voltage; V1 first change voltage; V2 second change voltage; VC comparative voltage; Vg gate voltage; Vm mirror voltage; Vref reference potential; Vth threshold voltage.

1. A driving circuit for a power semiconductor element, the driving circuit comprising:
a first gate voltage control circuit to control a gate voltage of the power semiconductor element in response to a turn-on command of the power semiconductor element, in a first time region, a second time region, and a third time region in order, in different manners for the respective time regions, to thereby cause the gate voltage to reach a mirror voltage,
the gate voltage reaching the mirror voltage in the second time region or the third time region according to magnitude of a main current flowing through the power semiconductor element,
the driving circuit further comprising a second gate voltage control circuit to control the gate voltage greater than or equal to the mirror voltage.

2. The driving circuit for a power semiconductor element according to claim 1, wherein
the first gate voltage control circuit is configured to:
increase the gate voltage to a first voltage at a first slope in the first time region;
increase the gate voltage from the first voltage at a second slope gentler than the first slope in the second time region; and
increase the gate voltage to the mirror voltage at a third slope gentler than the first slope and steeper than second slope in the third time region when the gate voltage has not reached the mirror voltage in the second time region, and
the second gate voltage control circuit is configured to increase the gate voltage from the mirror voltage at a fourth slope steeper than the third slope.

3. The driving circuit for a power semiconductor element according to claim 2, wherein the first gate voltage control circuit includes:
a first voltage generation circuit to generate the first voltage;
a first change voltage generation circuit to generate a first change voltage that increases at a first change rate corresponding to the second slope, and to superimpose the generated first change voltage on the first voltage;
a second change voltage generation circuit to generate a second change voltage that increases at a second change rate greater than the first change rate,
an adder circuit to output the first change voltage superimposed on the first voltage in the second time region and to generate a third change voltage that increases at a change rate corresponding to the second slope based on the first voltage, the first change voltage, and the second change voltage in the third time region, and
a buffer circuit to transfer the voltage generated by the adder circuit to a gate of the power semiconductor element.

4. The driving circuit for a power semiconductor element according to claim 3, wherein
the first change voltage generation circuit and the second change voltage generation circuit start generating the first change voltage and the second change voltage, respectively, upon receipt of the turn-on command, and
the second time region switches to the third time region when a sum of the first voltage and the first change voltage becomes equal to the second change voltage.

5. The driving circuit for a power semiconductor element according to claim 3, wherein the first voltage generation circuit includes a Zener diode to limit the gate voltage to the first voltage when the gate voltage of the power semiconductor element rises.

6. The driving circuit for a power semiconductor element according to claim 3, wherein
the adder circuit includes a diode having:
a cathode to which the first voltage and the first change voltage are applied; and
an anode to which the second change voltage is applied, and
a voltage of the cathode of the diode is input to the buffer circuit.

7. The driving circuit for a power semiconductor element according to claim 3, wherein
each of the first change voltage generation circuit and the second change voltage generation circuit includes a first-order lag circuit including a resistive element and a capacitive element,
a step input corresponding to the turn-on command is input to the first-order lag circuit, and
an output of the first-order lag circuit corresponds to the first change voltage or the second change voltage.

8. The driving circuit for a power semiconductor element according to claim 3, wherein each of the first change voltage generation circuit and the second change voltage generation circuit includes a capacitive element and a current source to input a current to the capacitive element in response to the turn-on command, and outputs a voltage of the capacitive element as the first change voltage or the second change voltage.

9. The driving circuit for a power semiconductor element according to claim 3, wherein
the second gate voltage control circuit includes a comparator to compare the first change voltage or the second change voltage with a comparative voltage that is constant, and
when the first change voltage or the second change voltage becomes greater than the comparative voltage, the comparator outputs, as a high-level output, a supply voltage of the driving circuit to the gate of the power semiconductor element.

10. The driving circuit for a power semiconductor element according to claim 2, wherein
the driving circuit further includes a mirror voltage detection circuit to detect a timing at which the gate voltage has reached the mirror voltage, and
the second gate voltage control circuit outputs a supply voltage supplied to the driving circuit to a gate of the power semiconductor element based on the timing detected by the mirror voltage detection circuit.

11. The driving circuit for a power semiconductor element according to claim 10, wherein the mirror voltage detection circuit includes:
a differentiating circuit to output a time derivative of the gate voltage;
a binarization circuit to convert an output of the differentiating circuit into a binary value of high level and low level and output a value after the conversion; and
an edge detection circuit to detect an edge of an output waveform of the binarization circuit.

12. A power module comprising:
a power semiconductor element; and
the driving circuit according for the power semiconductor element, the driving circuit comprising:
a first gate voltage control circuit to control a gate voltage of the power semiconductor element in response to a turn-on command of the power semiconductor element, in a first time region, a second time region, and a third time region in order, in different manners for the respective time regions, to thereby cause the gate voltage to reach a mirror voltage,
the gate voltage reaching the mirror voltage in the second time region or the third time region according to magnitude of a main current flowing through the power semiconductor element,
the driving circuit further comprising a second gate voltage control circuit to control the gate voltage greater than or equal to the mirror voltage.

13. A method of driving a power semiconductor element, the method comprising:
increasing a gate voltage of the power semiconductor element to a first voltage at a first slope in a first time region after receipt of a turn-on command of the power semiconductor element;
increasing the gate voltage from the first voltage at a second slope gentler than the first slope in a second time region following the first time region;
increasing, when the gate voltage has not reached a mirror voltage in the second time region, the gate voltage to the mirror voltage at a third slope gentler than the first slope and steeper than the second slope in a third time region following the second time region; and
increasing the gate voltage from the mirror voltage at a fourth slope steeper than the third slope.

14. The method of driving a power semiconductor element according to claim 13, wherein increasing the gate voltage from the mirror voltage at the fourth slope is performed when a predetermined period has elapsed since receipt of the turn-on command.

15. The method of driving a power semiconductor element according to claim 13, further comprising detecting a timing at which the gate voltage has reached the mirror voltage,
wherein increasing the gate voltage from the mirror voltage at the fourth slope is performed based on the detected timing.

16. The method of driving a power semiconductor element according to claim 15, wherein detecting the timing at which the gate voltage has reached the mirror voltage includes:
detecting a time derivative of the gate voltage;
converting the detected time derivative into a binary value of high level and low level; and
detecting an edge of the time derivative converted into the binary value.
